(19) United States
(12) Patent Application Publication
(10) Pub. No.: US 2025/0098254 A1
(43) Pub. Date: Mar. 20, 2025

(54) EPITAXIAL FEATURES FOR MULTI-GATE DEVICES AND FABRICATION METHODS THEREOF

(71) Applicant: Taiwan Semiconductor Manufacturing Company, Ltd., Hsin-Chu (TW)

(72) Inventors: Hou-Hsueh Wu, Taipei City (TW); Wei Hsin Lin, Taichung City (TW); Hui-Hsuan Kung, Taichung City (TW); Yi-Lii Huang, Zhubei City (TW); Chih-Hsiao Chen, Taichung City (TW)

(21) Appl. No.: 18/422,412

(22) Filed: Jan. 25, 2024

Related U.S. Application Data
(60) Provisional application No. 63/583,083, filed on Sep. 15, 2023.

(51) Int. Cl. H01L 29/66; H01L 21/8234; H01L 27/088; H01L 29/06; H01L 29/423; H01L 29/775; H01L 29/78; H01L 29/786

(52) U.S. Cl. CPC H10D 64/017; H10D 30/014; H10D 30/024; H10D 30/43; H10D 30/6211; H10D 30/6735; H10D 30/6757; H10D 62/121; H10D 84/013; H10D 84/0158; H10D 84/038; H10D 84/834

(57) ABSTRACT

The present disclosure provides a semiconductor device and a method of forming the same. A method according to one embodiment includes forming a plurality of fins protruding from a substrate, forming first and second dummy gate stacks over the fins, and depositing a cover structure over the fins. A first portion of the cover structure extends between the first and second dummy gate stacks. The method also includes etching the fins to form a first trench between the first dummy gate stack and the first portion of the cover structure and a second trench between the second dummy gate stack and the first portion of the cover structure, removing the cover structure, epitaxially growing a first epitaxial feature from the first trench and a second epitaxial feature from the second trench. The first and second epitaxial features merge after rising above a top surface of the fins.

### PRIORITY DATA

This application claims priority to U.S. Provisional Patent Application No. 63/583,083, filed on Sep. 15, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

To improve performance of multi-gate transistors, efforts are invested to develop epitaxial features in source/drain regions. While conventional epitaxial features in source/drain regions are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 7, 8, and 15 illustrate perspective views of a workpiece during a bonding process according to the method of FIG. 1, according to one or more aspects of the present disclosure.

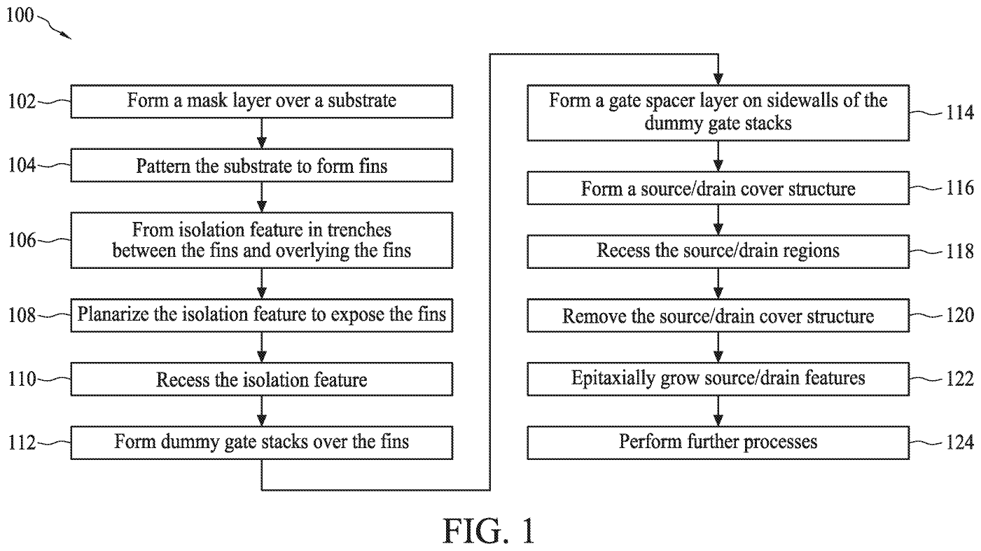

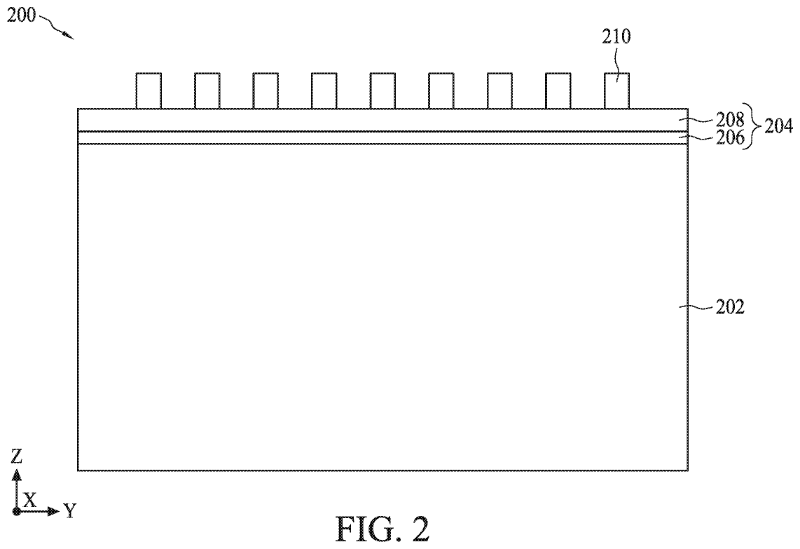

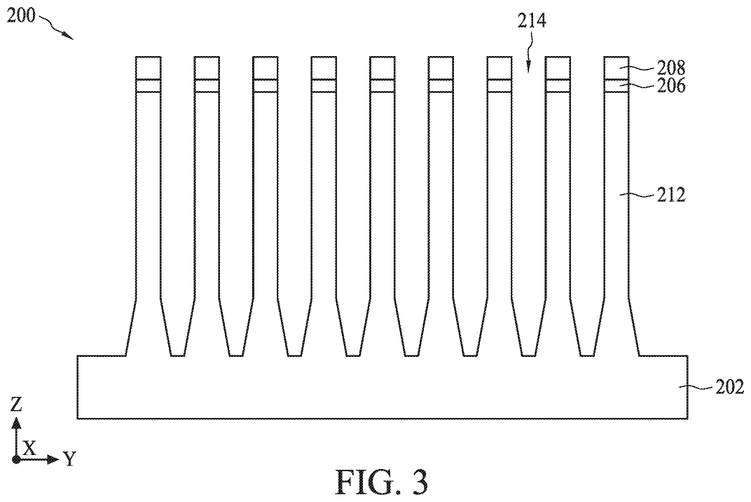

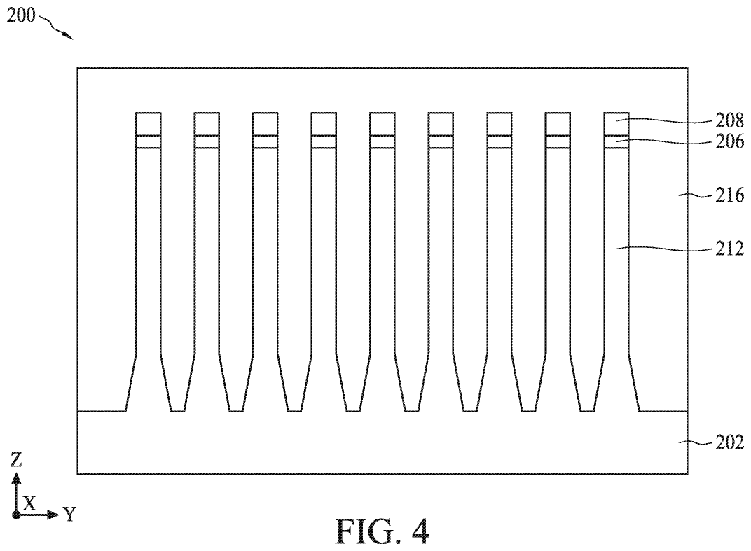

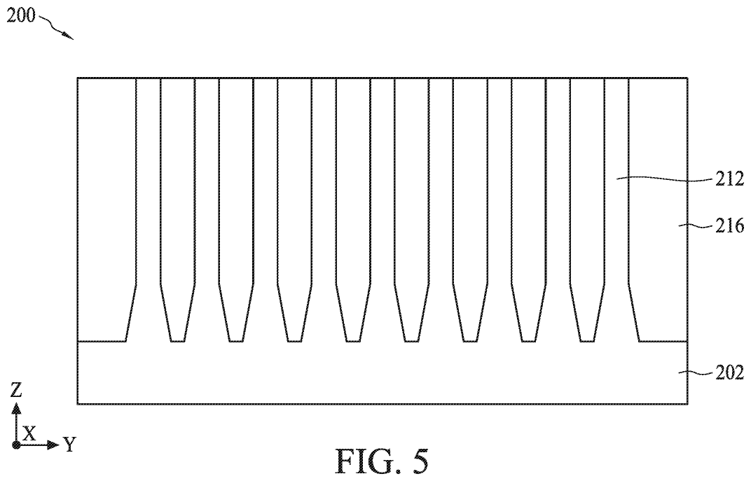

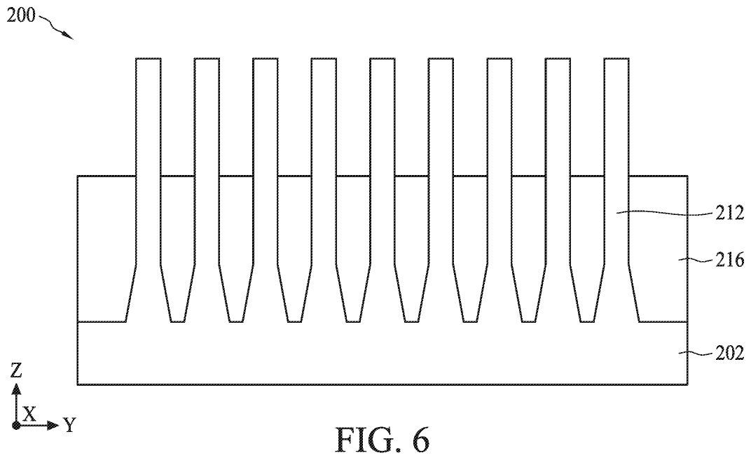

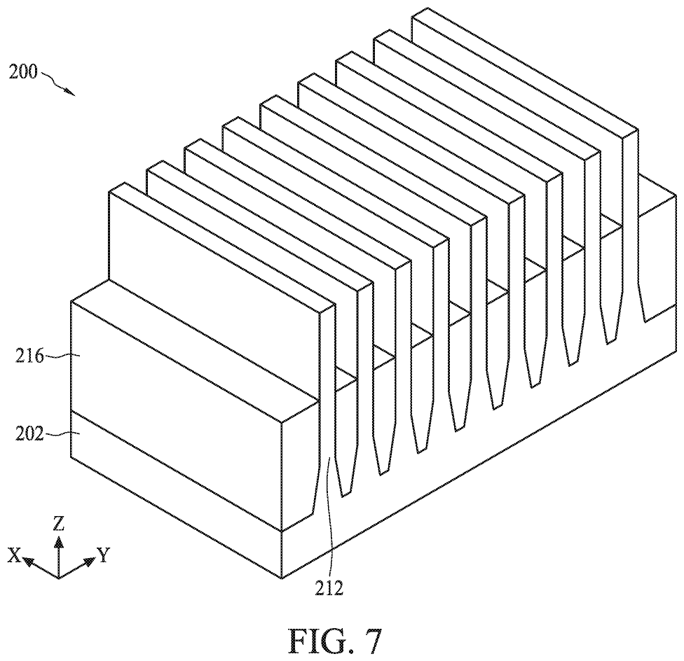

FIGS. 2, 3, 4, 5, 6, 9, 10, 11, 12, 13, 14, 15, 16, 18, 19, 20, 21, 22, 23, 24, 25, 26, 27, 28, 29, 30, 31, 32, 33, 34, 35, 36, 37, 38, 39, 40, 41A, 41B, 41C, 42A, 42B, and 42C illustrate top views and cross-sectional views of a workpiece during a fabrication process according to the method of FIG. 1, respectively, according to one or more aspects of the present disclosure.

FIG. 17 illustrates an epitaxial growth system that may be used during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be+/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to epitaxial features developed in source/drain regions (also referred to as source/drain epitaxial features or source/drain features) of multi-gate transistors having multiple fins. Source/drain region(s) may refer to a source or a drain, individually or collectively dependent upon the context.

Source/drain features epitaxially grown on multiple fins of multi-gate transistors may merge. The merged source/drain features confine subsequently formed source/drain contacts above the merged source/drain features. However, spacing between multiple fins and other factors may cause source/drain features not fully merge, such that some of the source/drain features may merge while gaps may still exist between some other unmerged source/drain features. Source/drain contacts may punch through the gaps and downwardly reach isolation features between the fins, which may introduce device degradation and restraint for device current tuning. In some embodiments of the present disclosure, profiles of the source/drain regions are adjusted prior to the epitaxial growth of source/drain features to improve the lateral merging of adjacent source/drain features.

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-42C, which are perspective, top, and cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in FIGS. 2-42C are perpendicular to one another. Throughout the present disclosure, like reference numerals denote like features, unless otherwise excepted. It is also appreciated that although FIGS. 2-42C illustrate formation of FinFETs as examples of multi-gate transistors, these examples are provided for illustrative purpose only and one of ordinary skill in the art would realize the present disclosure also contemplates the formation of MBC transistors (e.g., SGT transistors or GAA transistors).

Referring to FIGS. 1 and 2, method 100 includes a block 102 where to fabricate a semiconductor device 200 a mask layer 204 is formed over a substrate 202. The mask layer 204 is formed by, for example, thermal oxidation, chemical vapor deposition (CVD), atomic layer deposition (ALD), or any other appropriate method. In some embodiments, the substrate 202 is, for example, a p-type silicon substrate with an impurity concentration in a range of about 1×10¹⁵ cm⁻³ to about 2×10¹⁵ cm⁻³. In other embodiments, the substrate 202 is an n-type silicon substrate with an impurity concentration in a range of about 1×10¹⁵ cm⁻³ to about 2×10¹⁵ atoms cm⁻³. Alternatively, the substrate 202 may comprise another elementary semiconductor, such as germanium; a compound semiconductor including Group IV-IV compound semiconductors such as SiC and SiGe, Group III-V compound semiconductors such as GaAs, GaP, GaN, InP, InAs, InSb, GaAsP, AlGaN, AlInAs, AlGaAs, GaInAs, GaInP, and/or GaInAsP; or combinations thereof. In one embodiment, the substrate 202 is a silicon layer of an SOI (silicon-on insulator) substrate. Amorphous substrates, such as amorphous Si or amorphous SiC, or insulating material, such as silicon oxide may also be used as the substrate 202. The substrate 202 may include various regions that have been suitably doped with impurities (e.g., p-type or n-type conductivity).

The mask layer 204 includes, for example, a pad oxide (e.g., silicon oxide) layer 206 and a silicon nitride mask layer 208 in some embodiments. The pad oxide layer 206 may be formed by using thermal oxidation or a CVD process. The silicon nitride mask layer 208 may be formed by a CVD, plasma-enhanced chemical vapor deposition (PECVD), an atmospheric pressure chemical vapor deposition (APCVD), a low-pressure CVD (LPCVD), a high density plasma CVD (HDPCVD), an atomic layer deposition (ALD), a physical vapor deposition (PVD), such as a sputtering method, and/or other processes. The thickness of the pad oxide layer 206 is in a range of about 2 nm to about 15 nm, and the thickness of the silicon nitride mask layer 208 is in a range of about 2 nm to about 50 nm in some embodiments.

A mask pattern 210 is further formed over the mask layer 204. The mask pattern 210 is, for example, a resist pattern formed by lithography operations. By using the mask pattern 210 as an etching mask, a hard mask pattern of the pad oxide layer 206 and the silicon nitride mask layer 208 is formed. The width of the hard mask pattern is in a range of about 5 nm to about 40 nm in some embodiments. In certain embodiments, the width of the hard mask patterns is in a range of about 7 nm to about 12 nm.

Referring to FIGS. 1 and 3, method 100 includes a block 104 where the substrate 202 is patterned into a plurality of fins 212 by using the hard mask pattern as an etching mask. The patterning of the substrate 202 may include etching process, such as dry etching method and/or wet etching method, to form trenches 214. A height of the fins 212 may be in a range of about 20 nm to about 300 nm. In certain embodiments, the height is in a range of about 30 nm to about 60 nm. When the heights of the fins 212 are not uniform, the height from the substrate may be measured from the plane that corresponds to the average heights of the fins 212. The width of each of the fins 212 may be in a range of about 7 nm to about 15 nm.

In some embodiments, a bulk silicon wafer is used as the substrate 202. In some embodiments, other types of substrates may be used as the substrate 202. For example, a silicon-on-insulator (SOI) wafer may be used as a starting material, and the insulator layer of the SOI wafer constitutes the substrate 202 and the silicon layer of the SOI wafer is used for the fins 212.

Still referring to FIG. 3, nine fins 212 are disposed over the substrate 202. However, the number of fins is not limited to nine. There may be as few as one fin and more than nine fins. In addition, one or more dummy fins may be disposed adjacent to the sides of the fins to improve pattern fidelity in the patterning processes. The width of each fin 212 is in a range of about 5 nm to about 40 nm in some embodiments, and in a range of about 7 nm to about 15 nm in other embodiments. The width of trenches 214 between adjacent fins is in a range of about 5 nm to about 80 nm in some embodiments, and in a range of about 7 nm to about 15 nm in other embodiments. One skilled in the art will realize, however, that the dimensions and values recited throughout the descriptions are merely exemplary, and may be changed to suit different scales of integrated circuits.

Referring to FIGS. 1 and 4, method 100 includes a block 106 where an isolation feature 216 is formed in trenches 214 between the fins 212 and overlying the fins 212, so that the fins 212 are buried in the isolation feature 216. The isolation feature 216 is also referred to as shallow trench isolation (STI) feature. The isolation feature 216 includes one or more layers of insulating materials such as silicon oxide, silicon oxynitride or silicon nitride, formed by LPCVD (low pressure chemical vapor deposition), plasma-CVD or flowable CVD. In the flowable CVD, flowable dielectric materials instead of silicon oxide are deposited. Flowable dielectric materials, as their name suggest, can “flow” during deposition to fill gaps or spaces with a high aspect ratio. Usually, various chemistries are added to silicon-containing precursors to allow the deposited film to flow. In some embodiments, nitrogen hydride bonds are added. Examples of flowable dielectric precursors, particularly flowable silicon oxide precursors, include a silicate, a siloxane, a methyl silsesquioxane (MSQ), a hydrogen silsesquioxane (HSQ), an MSQ/HSQ a perhydrosilazane (TCPS), a perhydro-polysilazane (PSZ), a tetraethyl orthosilicate (TEOS), or a silyl-amine, such as trisilylamine (TSA). These flowable silicon oxide materials are formed in a multiple-operation process. After the flowable film is deposited, it is cured and then annealed to remove un-desired element(s). When the un-desired element(s) is removed, the flowable film densifies and shrinks. In some embodiments, multiple anneal processes are conducted. The flowable film is cured and annealed more than once. The flowable film may be doped with boron and/or phosphorous. The isolation feature 216 is formed by one or more layers of SOG, SiO, SiON, SiOCN, and/or fluorine-doped silicate glass (FSG) in some embodiments.

Referring to FIGS. 1 and 5, method 100 includes a block 108 where a planarization operation is performed so as to remove part of the isolation feature 216. The planarization operation may include a chemical mechanical polishing (CMP) and/or an etch-back process. The mask layer 204 may be removed, so that upper portion of the fins 212 is exposed.

Referring to FIGS. 1 and 6, method 100 includes a block 110 where the planarized isolation feature 216 is further recessed or pulled-back by a dry etching process, a wet etching process, and/or a combination thereof. The fins 212 rise above the isolation feature 216 after the recessing. In certain embodiments, the partially removing the isolation feature 216 are performed using a suitable etching process. For example, a wet etching process, such as, by dipping the substrate in hydrofluoric acid (HF) or phosphoric acid (H₃PO₄) may be performed. On the other hand, the partially removing the isolation feature 216 may be performed using a dry etching process. For example, a dry etching process using CHF₃ or BF₃ as etching gases may be used. A perspective view of the semiconductor device 200 showing the fins 212 rise above the isolation feature 216 is depicted in FIG. 7. The exposed portions of the fins 212 comprise channel regions, on which gate structures will be formed, and source/drain regions, in which epitaxial features (also referred to as source/drain epitaxial features or source/drain features) will be formed. In the present disclosure, a source and a drain are interchangeably used, and the term source/drain refers to either one of a source and a drain.

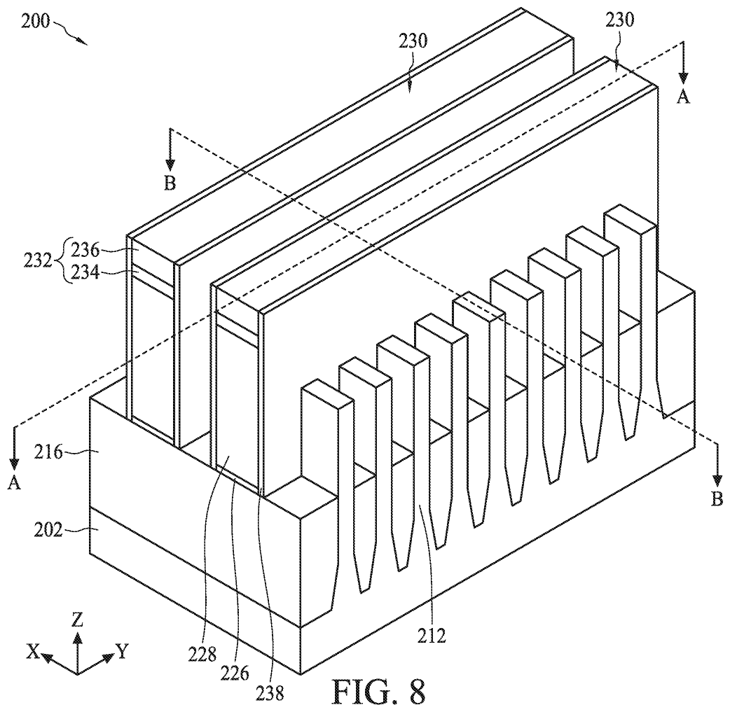

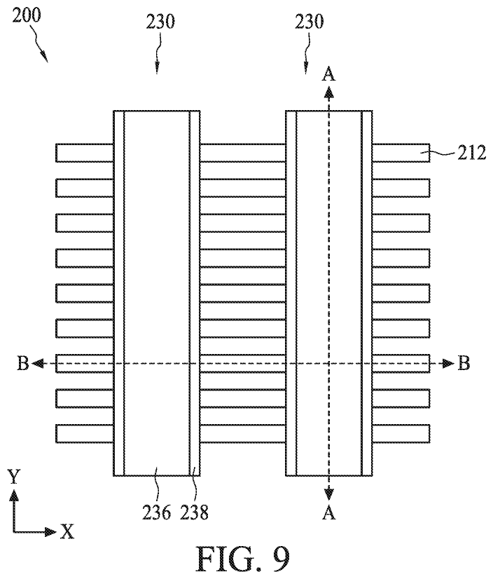

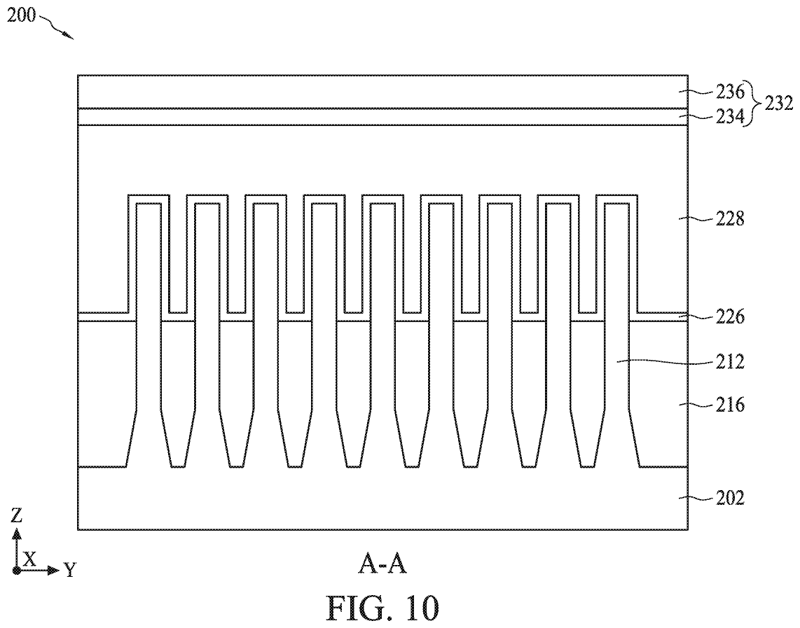

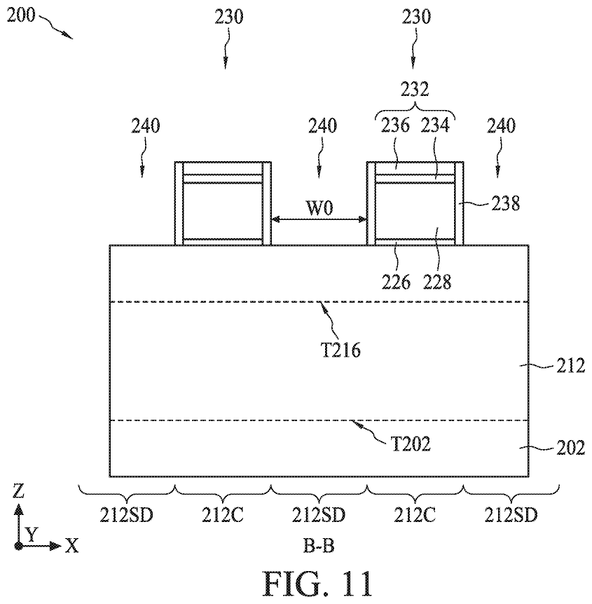

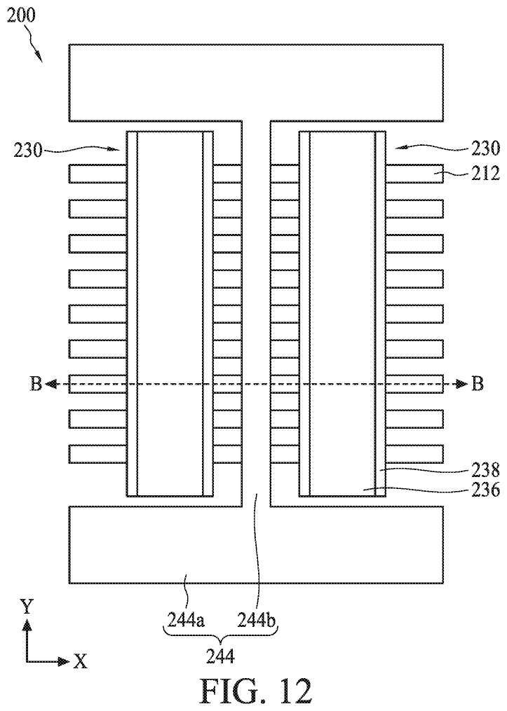

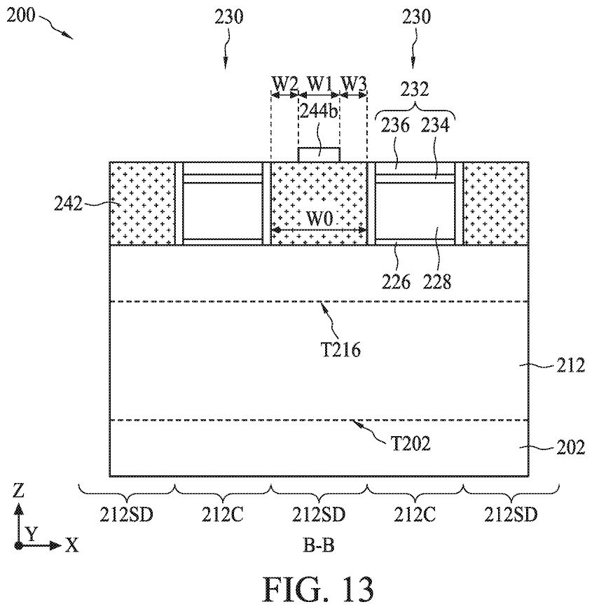

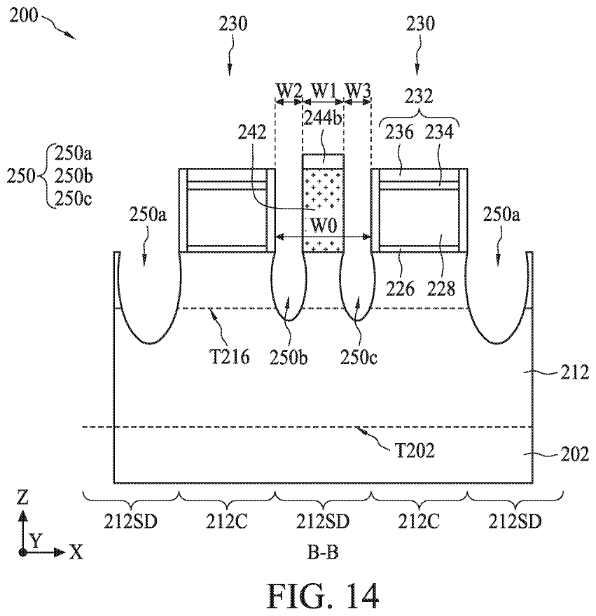

Referring to FIG. 1 and FIGS. 8-11, method 100 includes a block 112 where dummy gate stacks 230 are formed over channel regions of the fins 212. FIG. 8 illustrates a perspective view of the semiconductor device 200, FIG. 9 illustrates a top view of the semiconductor device 200, and FIGS. 10 and 11 illustrate cross-sectional views cut through A-A and B-B lines in FIG. 8, respectively. In some embodiments, a gate replacement process (or gate-last process) is adopted where the dummy gate stacks 230 serves as a placeholder to undergo various processes and is to be removed and replaced by the functional gate structure. Other processes and configuration are possible.

The formation of the dummy gate stacks 230 may include deposition of layers in the dummy gate stacks 230 and patterning of these layers. Referring to FIGS. 8-11 collectively, a dummy dielectric layer 226, a dummy electrode layer 228, and a gate-top hard mask layer 232 may be blanketly deposited over the semiconductor device 200. In some embodiments, the dummy dielectric layer 226 may be formed on the fins 212 using a chemical vapor deposition (CVD) process, an ALD process, an oxygen plasma oxidation process, or other suitable processes. In some instances, the dummy dielectric layer 226 may include silicon oxide. Thereafter, the dummy electrode layer 228 may be deposited over the dummy dielectric layer 226 using a CVD process, an ALD process, or other suitable processes. In some instances, the dummy electrode layer 228 may include polysilicon. For patterning purposes, the gate-top hard mask layer 232 may be deposited on the dummy electrode layer 228 using a CVD process, an ALD process, or other suitable processes. The gate-top hard mask layer 232, the dummy electrode layer 228 and the dummy dielectric layer 226 may then be patterned to form the dummy gate stacks 230. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 232 may include a silicon oxide layer 234 and a silicon nitride layer 236 over the silicon oxide layer 234.

Still referring to FIG. 1 and FIGS. 8-11, method 100 includes a block 114 where a gate spacer layer 238 is deposited over the dummy gate stacks 230. In some embodiments, the gate spacer layer 238 is deposited conformally over the workpiece 200, including over top surface and sidewalls of the dummy gate stacks 230. The term “conformally” may be used herein for ease of description of a layer having substantially uniform thickness over various regions. The gate spacer layer 238 may be a single layer or a multi-layer. The at least one layer in the gate spacer layer 238 may include silicon carbonitride, silicon oxycarbide, silicon oxycarbonitride, or silicon nitride. The gate spacer layer 238 may be deposited over the dummy gate stack 230 using processes such as, a CVD process, a subatmospheric CVD (SACVD) process, an ALD process, or other suitable process. In one embodiment, the gate spacer layer 238 includes a first layer and a second layer disposed over the first layer. The first layer may include silicon oxynitride and the second layer may include silicon nitride.

As the dummy gate stacks 230 and the gate spacer layer 238 are formed over the fins 212, the fins 212 are divided into channel regions 212C underlying the dummy gate stacks 230 (and the gate spacer layer 238) and source/drain regions 212SD that do not underlie the dummy gate stacks 230, as numerated in FIG. 11. The channel regions 212C are adjacent the source/drain regions 212SD with each channel region 212C disposed between two source/drain regions 212SD along the X direction. Opposing sidewalls of the gate spacer layer 238 define trenches 240 between adjacent dummy gate stacks 230. A width of the trenches 240 along the X direction is denoted as W0. The width W0 of trenches 240 may be in a range of about 40 nm to about 200 nm in some embodiments. FIG. 11 also shows a dashed line T216 marking a position of a top surface of the isolation feature 216 and a dashed line T202 marking a position of a top surface of the substrate 202.

Referring to FIG. 1 and FIGS. 12-13, method 100 includes a block 116 where a source/drain cover structure (or simply as cover structure) 244 is formed on the semiconductor device 200. FIG. 12 illustrates a top view of the semiconductor device 200, and FIG. 13 illustrates a cross-sectional view cut through B-B lines in FIG. 12. In some embodiments, the cover structure 244 may be a patterned resist layer or a patterned hard mask. In some embodiments, a bottom anti-reflective coating (BARC) layer 242 is first deposited on the semiconductor device 200, which fills up the trenches 240 between adjacent dummy gate stacks 230. The cover structure 244 is subsequently formed on the BARC layer 242. In one example, the BARC layer 242 includes organic BARC material formed by a spin-coating technique, and the cover structure 244 is a patterned hard mask formed by patterning a hard mask layer. In the illustrated embodiment, the top surface of the BARC layer 242 is coplanar with the top surface of the dummy gate stacks 230, such that the dummy gate stacks 230 are still exposed. In other embodiments, the BARC layer 242 may cover the semiconductor device 200 with the dummy gate stacks 230 covered underneath.

Referring to FIG. 12, the cover structure 244 includes at least one base portion 244a and at least one protruding portion 244b. In the illustrated embodiment, the cover structure 244 includes two base portions 244a sandwiching the dummy gate stacks 230 along the Y direction and one protruding portion 244b connecting the two base portions 244a. Each of the base portions 244a extends lengthwise in the same direction as the fins 212 along the X direction, and the protruding portion 244b extends lengthwise in the same direction as the dummy gate stacks 230 in the Y direction. The one or more base portions 244a mainly provide mechanical support to the protruding portion 244b from gate-side. Thus, the base portion 244a is also referred to as a gate-side portion 244a. The protruding portion 244b protrudes from the base portion 244a and extends across source/drain regions of the fins 212 in the Y direction. Thus, the protruding portion 244b may be referred to herein as the source/drain cover portion 244b as the context requires.

With the ever-decreasing gate-to-gate spacing and increasing number of fins formed in one active region, the shape of the source/drain cover portion 244b in a top view may resemble a long and thin line, which is vulnerable during manufacturing operations and may become easily peeled off if there is no base portion(s) 244a to improve mechanical integrity of the cover structure 244. In the illustrated embodiment, there are two base portions 244a connected to both ends of the source/drain cover portion 244b. In other embodiments, there may be a single base portion 244a connected to one end of the source/drain cover portion 244b, which will also be discussed in further detail below.

Referring to FIG. 13, the source/drain cover portion 244b has a width denoted as W1, which is smaller than the spacing W0 between adjacent dummy gate stacks 230. The source/drain cover portion 244b is positioned between adjacent dummy gate stacks 230, leaving a first opening with a width W2 on one side of the source/drain cover portion 244b and a second opening with a width W3 on another side of the source/drain cover portion 244b. That is, W0=W1+W2+W3. In some embodiments, the source/drain cover portion 244b is positioned at the center of the source/drain region 212SD with W2=W3. In some embodiments, the source/drain cover portion 244b is closer to one of the adjacent dummy gate stacks 230 with W2<W3 or W2>W3. In various embodiments, each of the widths W2 and W3 may be at least about 10% of the width W0. If W2 and W3 is less than about 10% of the width W0, the opening may become too small for subsequent etching process to recess the fins 212 in the source/drain regions 212SD. In some embodiments, the width W1 may be at least about 10% of the width W0. If W1 is less than about 10% of the width W0, the source/drain cover portion 244b may be too thin and become easily peeled off during manufacturing operations.

Referring to FIG. 1 and FIG. 14, method 100 includes a block 118 where an etching process is performed through openings in the source/drain regions 212SD that are not covered by the dummy gate stacks 230 (with the gate spacer layer 238) and the source/drain cover portion 244b. The corresponding source/drain regions of the fins 212 are recessed to form source/drain trenches 250. In some embodiments, the source/drain regions of the fins 212 are etched by a dry etch or a suitable etching process to form the source/drain trenches 250. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In the source/drain regions 212SD where that is no source/drain cover portion 244b-such as the left one and right one of the source/drain regions 212SD in FIG. 14-a single large source/drain trench 250a is formed with an opening width W0. In the source/drain regions 212SD that is partially covered by the source/drain cover portion 244b-such as the center source/drain region 212SD in FIG. 14—two small source/drain trenches 250b and 250c are formed with a first opening width W2 and a second opening width W3, respectively. The volume of the source/drain trench 250a is larger than either of the source/drain trenches 250b and 250c. Further, the volume of the source/drain trench 250a is larger than the sum of the source/drain trenches 250b and 250c. Still further, a depth of the source/drain trench 250a is larger than the source/drain trenches 250b and 250c due to etchant loading effect associated with a larger opening. In the illustrated embodiment, each of the source/drain trenches 250a, 250b, 250c extends below the dashed line T216. In some other embodiments, the source/drain trenches 250a extend below the dashed line T216, while the source/drain trenches 250b and 250c remain above the dashed line T216.

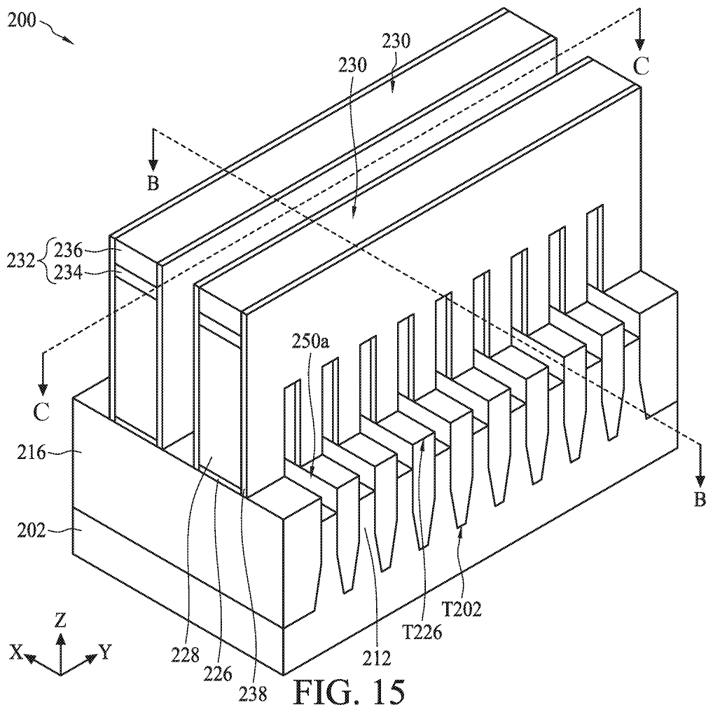

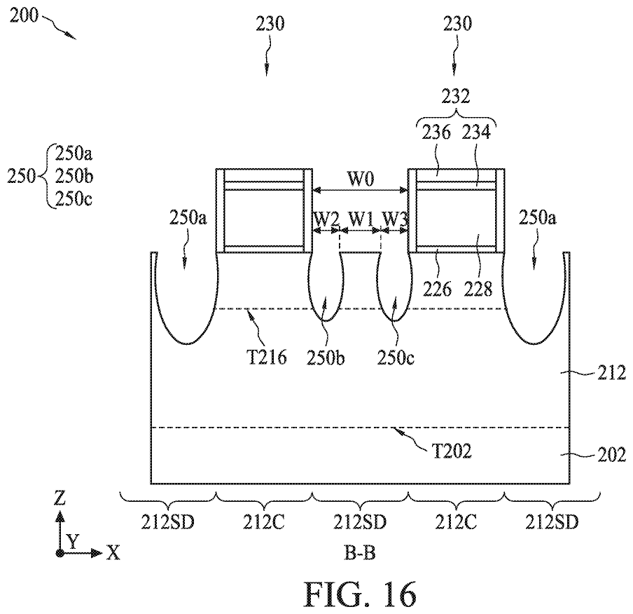

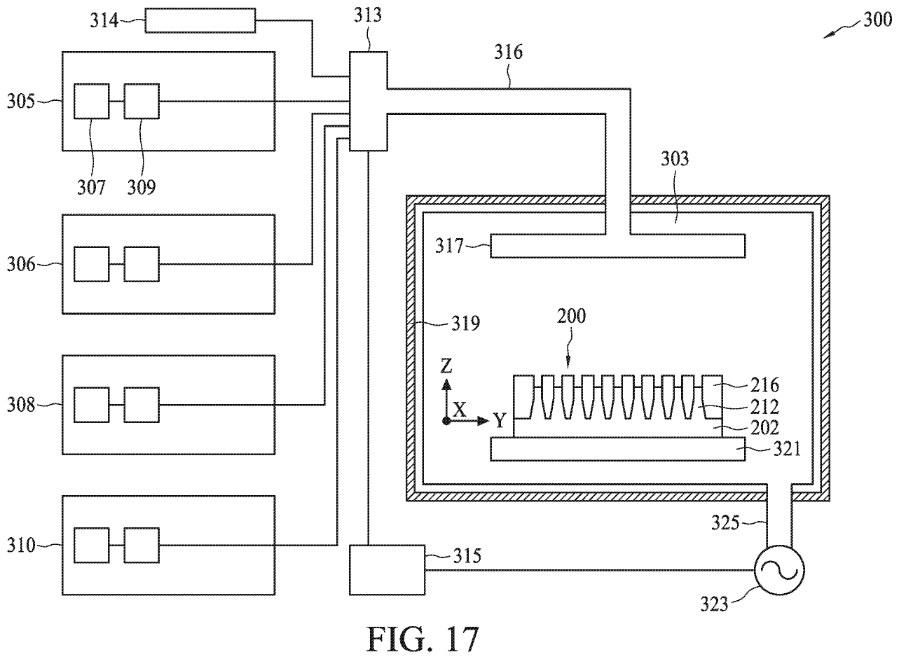

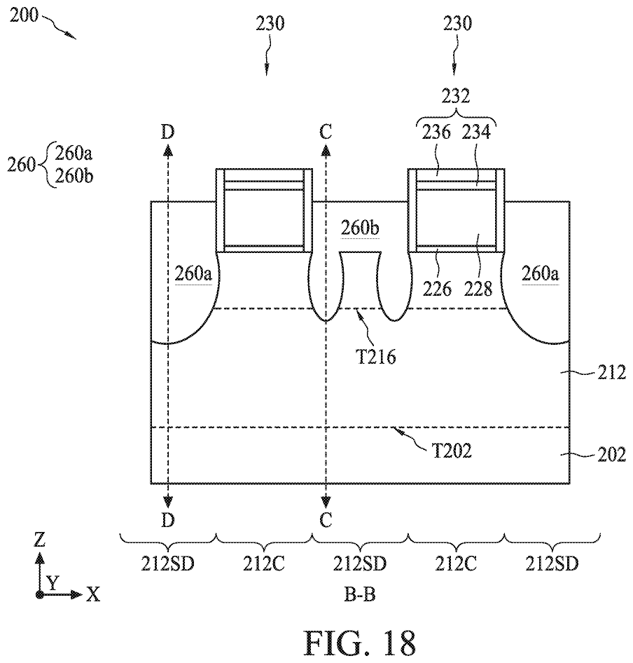

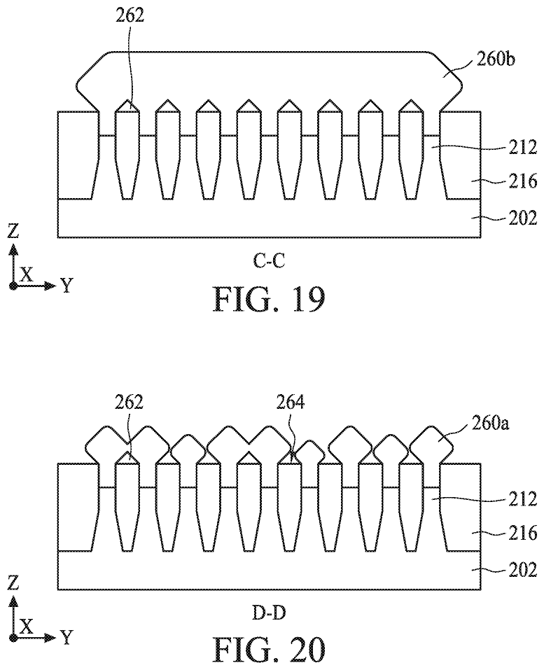

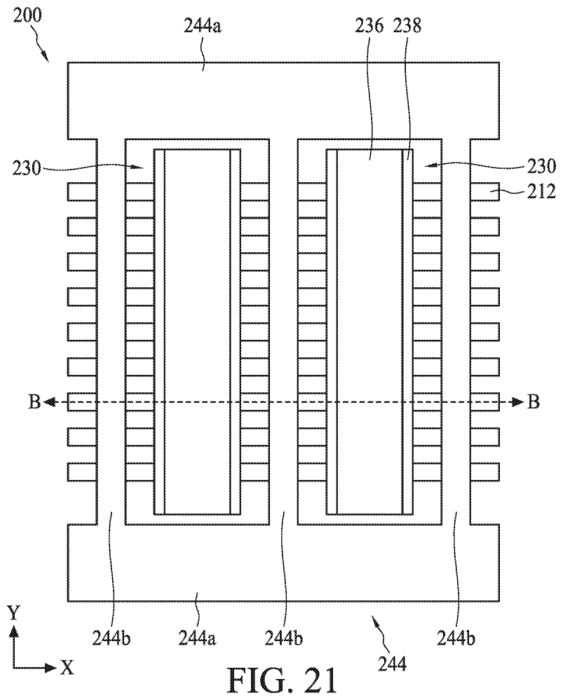

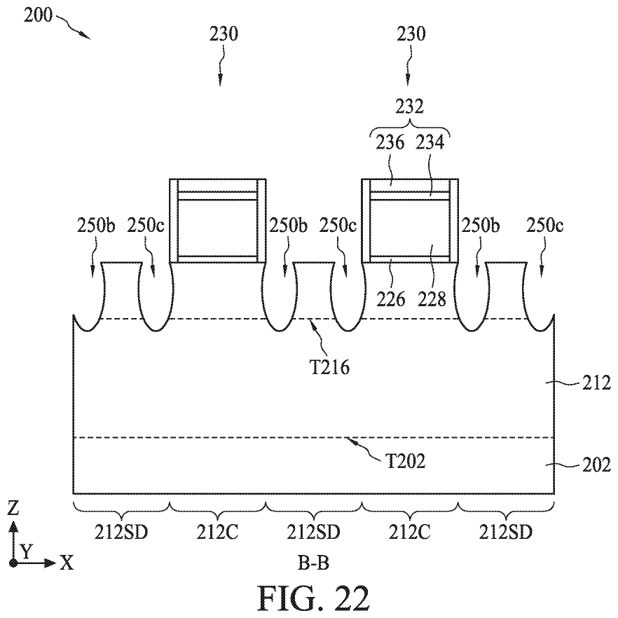

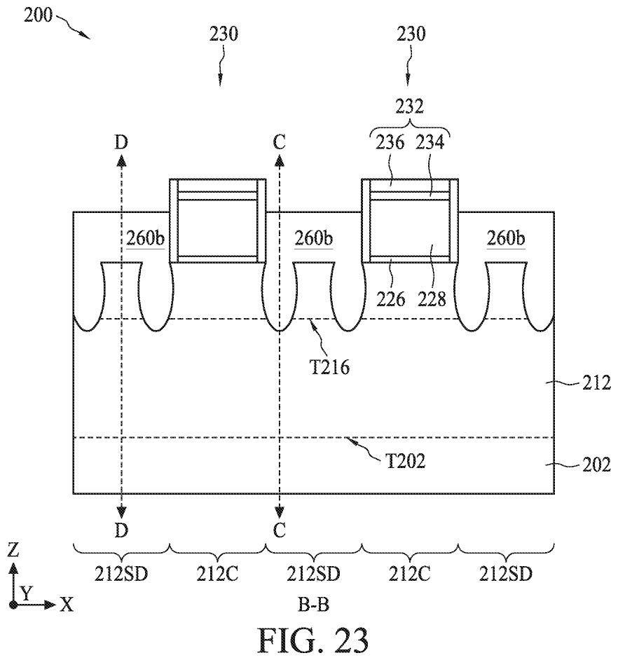

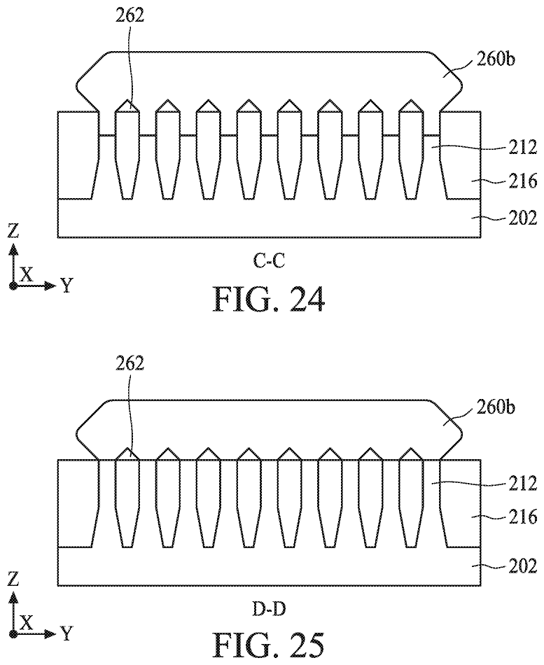

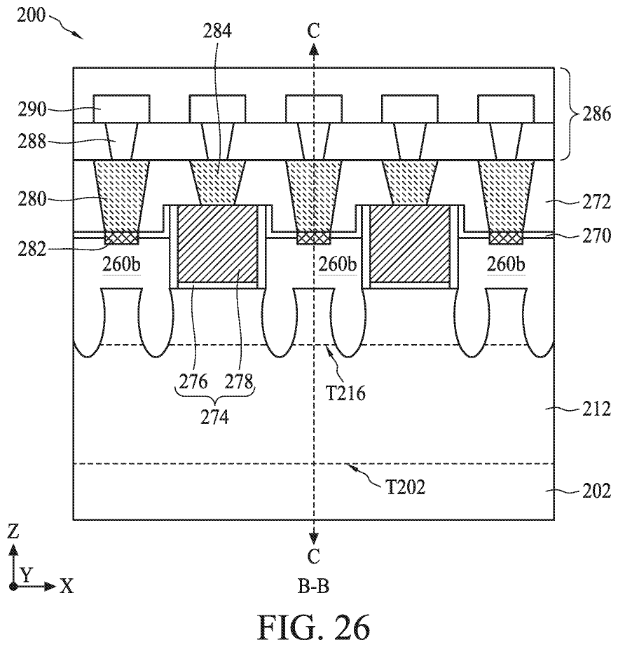

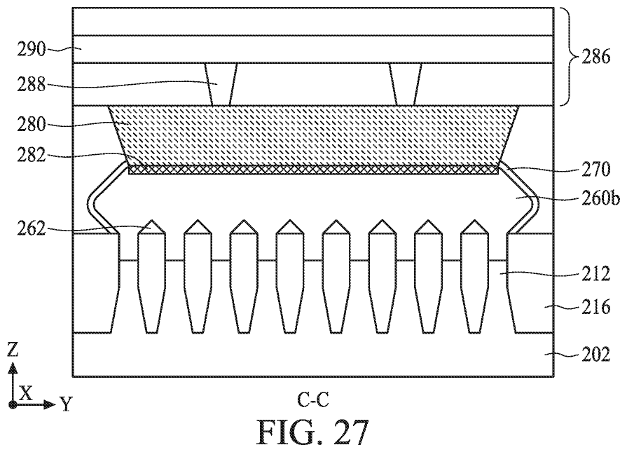

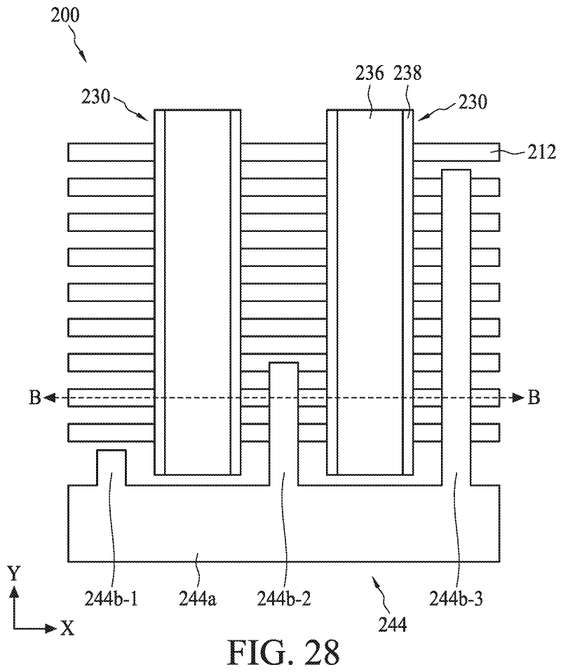

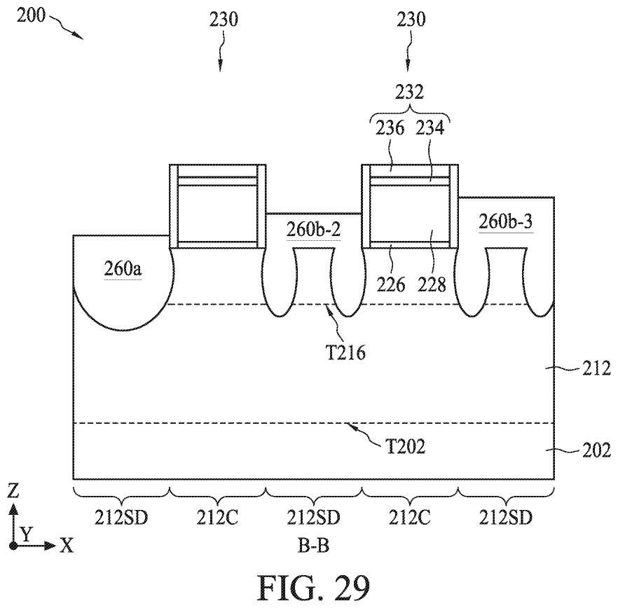

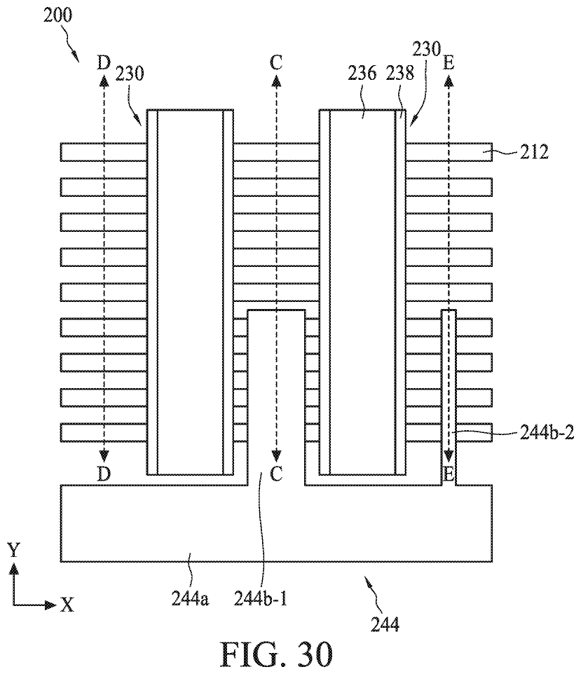

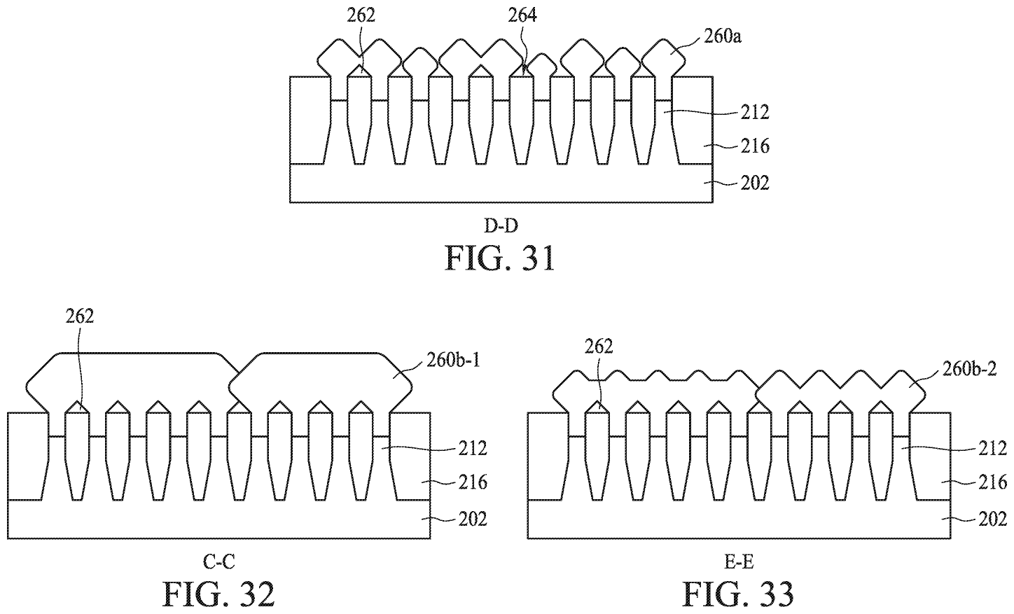

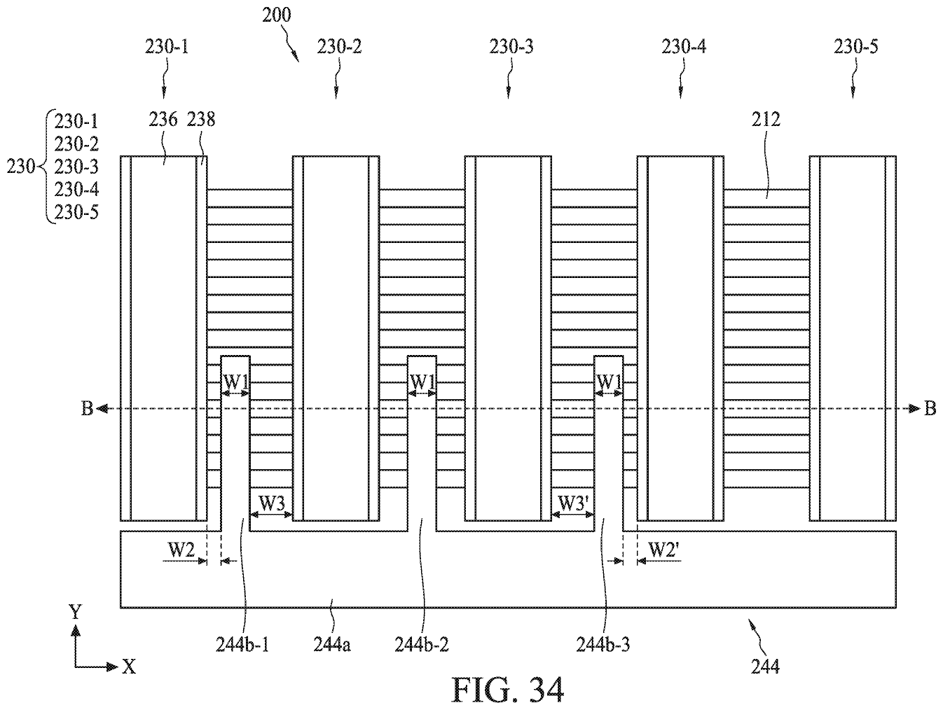

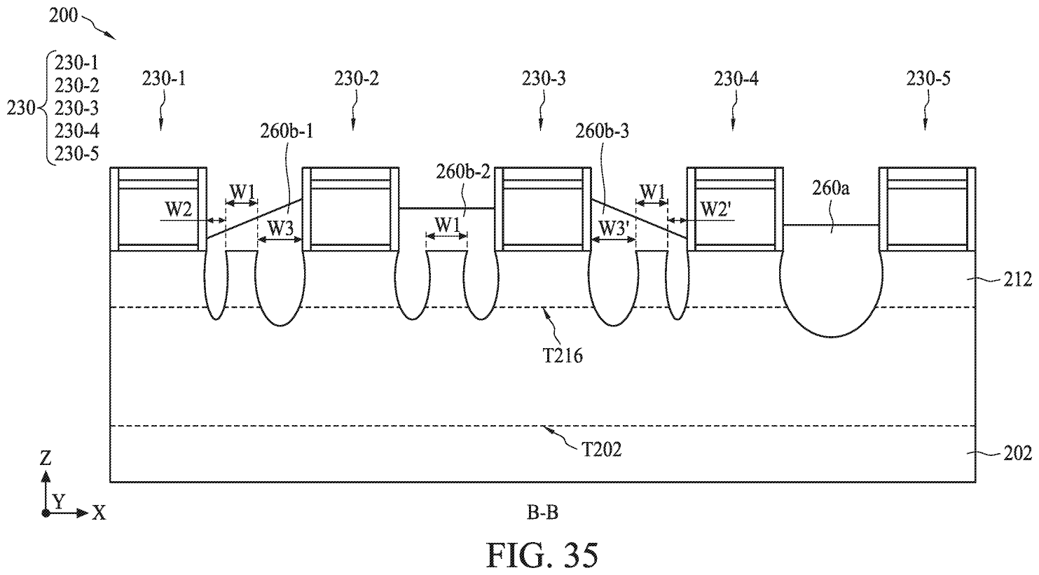

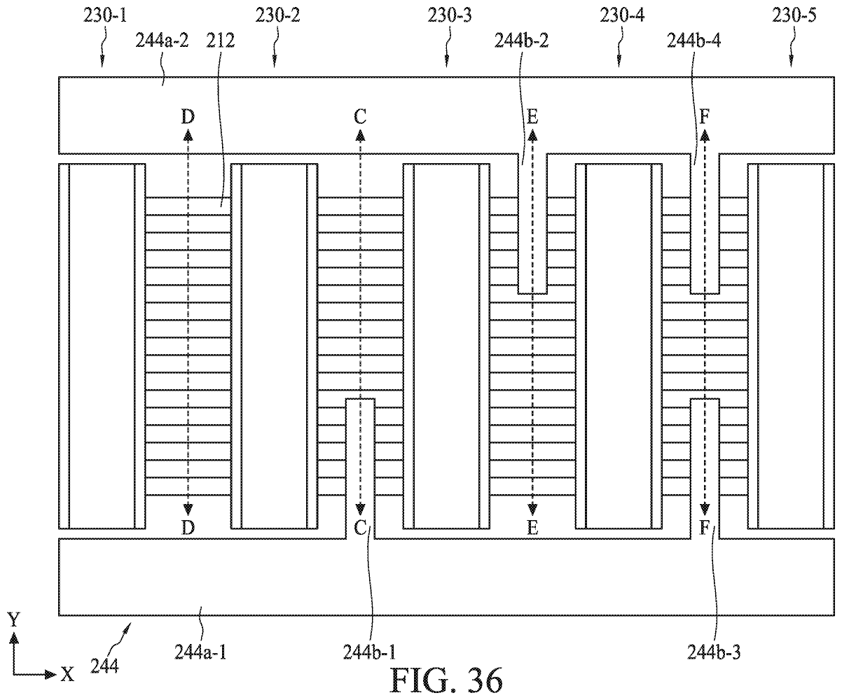

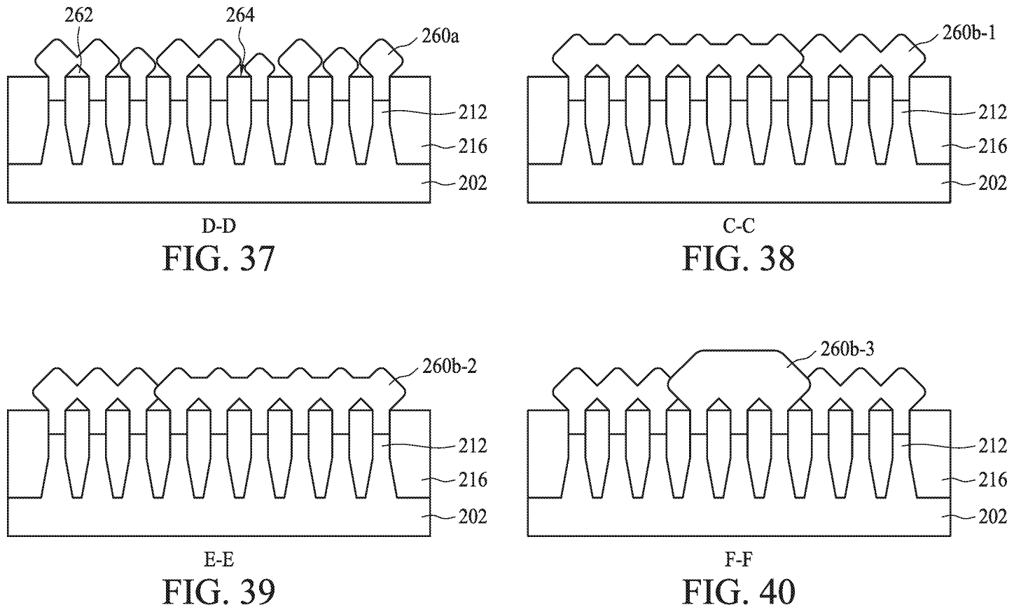

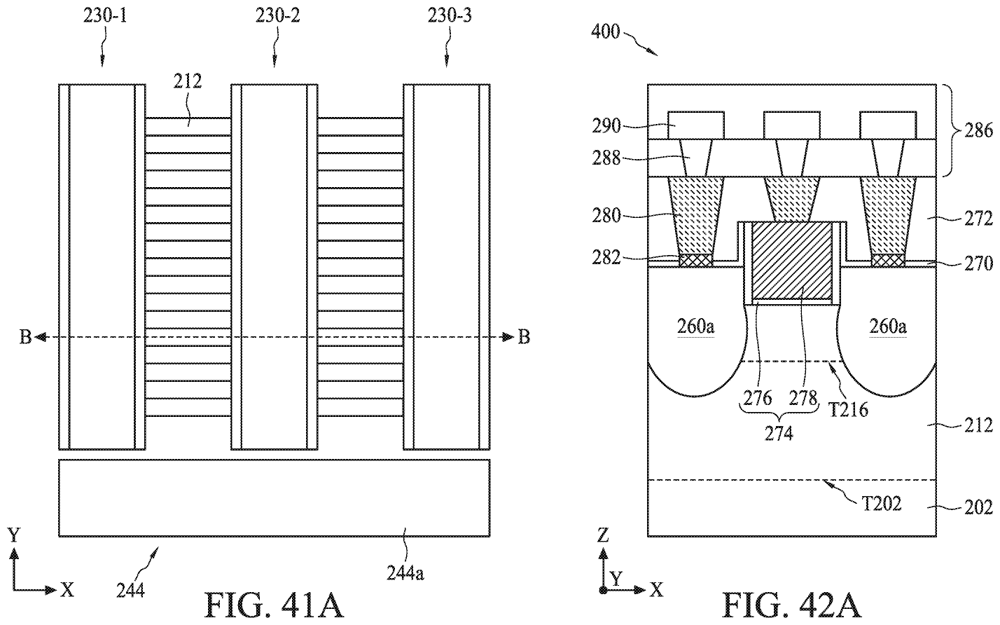

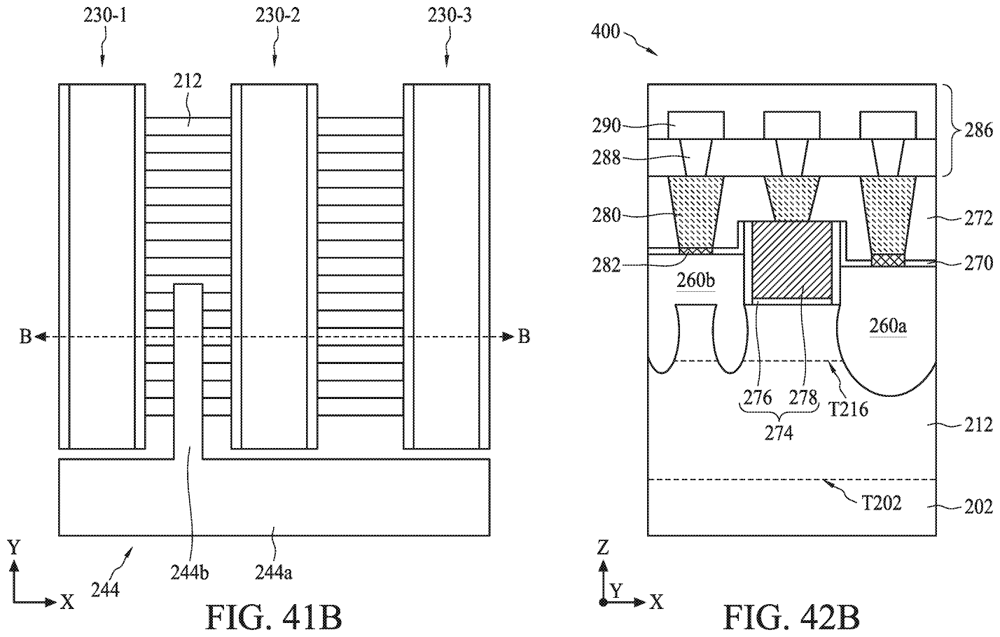

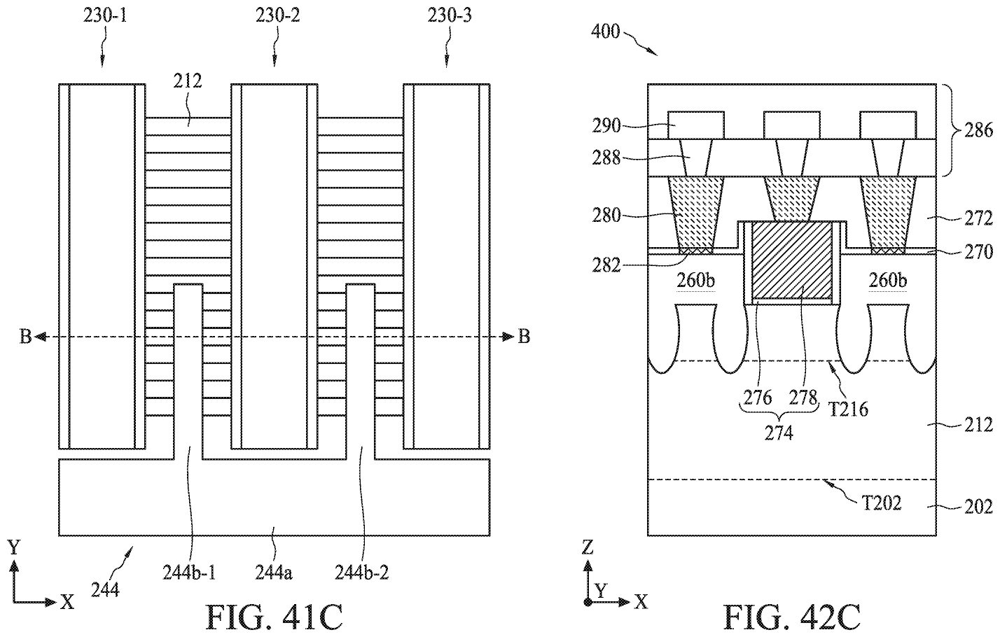

Referring to FIG. 1 and FIGS. 15-16, method 100 includes a block 120 where the BARC layer 242 and the cover structure 244 are removed from the semiconductor device 200. FIG. 15 illustrates a perspective view of the semiconductor device 200, and FIG. 16 illustrates a cross-sectional view cut through B-B line in FIG. 15. Operations at block 120 may include any suitable etching process including wet etching, dry etching, reactive ion etching, ashing, and/or other suitable technique. At the conclusion of operations at block 118, a middle portion of the fins 212 between the source/drain trenches 250b and 250c and other portions of the fins 212 underneath the dummy gate stacks 230 have top surfaces that are level.

Referring to FIGS. 1 and 17, method 100 includes a block 122 where an epitaxial growth process is performed to form source/drain features in the semiconductor device 200 through an epitaxial growth system 300. The semiconductor device 200 is placed on a mounting platform 321 in order to position and control the substrate 202 and the fins 212 during the epitaxial growth processes. The cross-sectional view of the semiconductor device 200 in FIG. 17 is a cut through source/drain regions of the fin 212 along the C-C line in FIG. 15.

The epitaxial growth system 300 may be utilized to receive precursor materials from a first precursor delivery system 305, a second precursor delivery system 306, a third precursor delivery system 308, and a fourth precursor delivery system 310, and form layers of materials (e.g., the source/drain features) on the fins 212. In an embodiment the first precursor delivery system 305, the second precursor delivery system 306, the third precursor delivery system 308, and the fourth precursor delivery system 310 work in conjunction with one another to supply the various different precursor materials to an epitaxial growth chamber 303 wherein the semiconductor device 200 are placed. The first precursor delivery system 305, the second precursor delivery system 306, the third precursor delivery system 308, and the fourth precursor delivery system 310 may have physical components that are similar with each other.

For example, the first precursor delivery system 305, the second precursor delivery system 306, the third precursor delivery system 308, and the fourth precursor delivery system 310 may each include a gas system 307 and a flow controller 309. In an embodiment in which the first precursor is stored in a gaseous state, the gas system 307 may supply the first precursor to the epitaxial growth chamber 303.

The gas system 307 may be a vessel, such as a gas storage tank, that is located either locally to the epitaxial growth chamber 303 or else may be located remotely from the epitaxial growth chamber 303. In another embodiment, the gas system 307 may be a facility that independently prepares and delivers the first precursor to the flow controller 309. Any suitable source for the first precursor may be utilized as the gas system 307, and all such sources are fully intended to be included within the scope of the embodiments. The gas system 307 may supply the desired precursor to the flow controller 309. The flow controller 309 may be utilized to control the flow of the precursor to the precursor gas controller 313 and, eventually, to the epitaxial growth chamber 303, thereby also helping to control the pressure within the epitaxial growth chamber 303. The flow controller 309 may be, e.g., a proportional valve, a modulating valve, a needle valve, a pressure regulator, a mass flow controller, combinations of these, or the like. Any suitable method for controlling and regulating the flow of the first precursor may be utilized, and all such components and methods are fully intended to be included within the scope of the embodiments.

Additionally, in an embodiment in which the first precursor is stored in a solid or liquid state, the gas system 307 may also store or receive a carrier gas and the carrier gas may be introduced into a precursor canister (not separately illustrated), which stores the first precursor in the solid or liquid state. The carrier gas is then used to push and carry the first precursor as it either evaporates or sublimates into a gaseous section of the precursor canister before being sent to the precursor gas controller 313. Any suitable method and combination of units may be utilized to provide the first precursor, and all such combinations of units are fully intended to be included within the scope of the embodiments.

The first precursor delivery system 305, the second precursor delivery system 306, the third precursor delivery system 308, and the fourth precursor delivery system 310 may supply their individual precursor materials into a precursor gas controller 313. The precursor gas controller 313 connects and isolates the first precursor delivery system 305, the second precursor delivery system 306, the third precursor delivery system 308, and the fourth precursor delivery system 310 from the epitaxial growth chamber 303 in order to deliver the desired precursor materials to the epitaxial growth chamber 303 (discussed further below).

The precursor gas controller 313 may include such devices as valves, flow meters, sensors, and the like to control the delivery rates of each of the precursors, and may be controlled by instructions received from a control unit. The precursor gas controller 313, upon receiving instructions from the control unit, may open and close valves so as to connect one or more of the first precursor delivery system 305, the second precursor delivery system 306, the third precursor delivery system 308, and the fourth precursor delivery system 310 to the epitaxial growth chamber 303 and direct a desired precursor material through a manifold 316, into the epitaxial growth chamber 303, and to a showerhead 317. The showerhead 317 may be utilized to disperse one or more of the chosen precursor materials into the epitaxial growth chamber 303 and may be designed to evenly disperse the precursor material in order to minimize undesired process conditions that may arise from uneven dispersal. In an embodiment the showerhead 317 may have a circular design with openings dispersed evenly around the showerhead 317 to allow for the dispersal of the desired precursor materials into the epitaxial growth chamber 303.

As one of ordinary skill in the art will recognize, the introduction of precursor materials to the epitaxial growth chamber 303 through a single showerhead 317 or through a single point of introduction as described above is intended to be illustrative only and is not intended to be limiting to the embodiments. Any number of separate and independent showerheads 317 or other openings to introduce the various precursor materials into the epitaxial growth chamber 303 may be utilized. All such combinations of showerheads and other points of introduction are fully intended to be included within the scope of the embodiments.

The epitaxial growth chamber 303 may receive the desired precursor materials and expose the precursor materials to the fins 212, and the epitaxial growth chamber 303 may be a shape suitable for dispersing the precursor materials and contacting the precursor materials with the fins 212. In the illustrated embodiment, the epitaxial growth chamber 303 has a cylindrical sidewall and a bottom. The epitaxial growth chamber 303 is not limited to a cylindrical shape, and any other suitable shape, such as a hollow square tube, an octagonal shape, or the like, may be utilized. Furthermore, the epitaxial growth chamber 303 may be surrounded by a housing 319 made of material that is inert to the various process materials. As such, while the housing 319 may be any suitable material that can withstand the chemistries and pressures involved in the deposition process, in an embodiment the housing 319 may be steel, stainless steel, nickel, aluminum, alloys of these, combinations of these, and like.

Within the epitaxial growth chamber 303, the substrate 202 may be placed on a mounting platform 321 in order to position and control the substrate 202 and the fins 212 during the epitaxial growth processes. The mounting platform 321 may include heating mechanisms in order to heat the substrate 202 during the epitaxial growth processes. Additionally, the epitaxial growth chamber 303 and the mounting platform 321 may be part of a cluster tool system (not shown). The cluster tool system may be used in conjunction with an automated handling system in order to position and place the semiconductor device 200 into the epitaxial growth chamber 303 prior to the epitaxial growth processes, position, hold the semiconductor device 200 during the epitaxial growth processes, and remove the semiconductor device 200 from the epitaxial growth chamber 303 after the epitaxial growth processes.

The epitaxial growth chamber 303 may also have an exhaust outlet 325 for exhaust gases to exit the epitaxial growth chamber 303. A vacuum pump 323 may be connected to the exhaust outlet 325 of the epitaxial growth chamber 303 in order to help evacuate the exhaust gases. The vacuum pump 323, under control of the control unit 315, may also be utilized to reduce and control the pressure within the epitaxial growth chamber 303 to a desired pressure and may also be utilized to evacuate precursor materials from the epitaxial growth chamber 303 in preparation for the introduction of the next precursor material.

In preparation for the formation of the source/drain features, a first precursor material is placed into or formed by the first precursor delivery system 305. For example, in an embodiment in which a doped semiconductor material such as silicon phosphorous is to be grown, the first precursor material may be a silicon-containing precursor material such as dichlorosilane (DCS), although other suitable precursors, such as silane (SiH₄) or disilane (Si₂H₆), may also be utilized. All suitable precursor materials are fully intended to be included within the scope of the embodiments.

Additionally, a second precursor material may be placed into or formed by the second precursor delivery system 306. In the embodiment the second precursor may be used to provide a doping material that complements the semiconductor material present in the first precursor material. For example, in an embodiment in which a layer of silicon doped with phosphorous (SiP) is to be grown as the source/drain features and the first precursor material is dichlorosilane, the second precursor material may be a material that comprises a suitable dopant such as phosphorous (P). In a particular embodiment the second precursor material is PH₃. However, any suitable dopant containing material, such as arsenic (As) or antimony (Sb), may be utilized and placed within the second precursor delivery system 306.

In addition to the first precursor material and the second precursor material that are collectively utilized to grow the epitaxial material (e.g., SiP), an etching precursor may also be utilized during the growth process, and may be placed in the third precursor delivery system 308. In an embodiment in which the material to be grown will at least partially deposit on materials other than the exposed fins 212 (such as by growing on the exposed surfaces of the isolation feature 216), the addition of an etching precursor will work to remove epitaxially grown material from these undesired locations, and helps to cause the epitaxial growth be more selective. In an embodiment the etching precursor is a precursor that will remove undesired growth of the grown material while still allowing for growth of the desired material over the fins 212, and may be an etchant such as hydrochloric acid (HCl). Other suitable etching precursor may be utilized.

Still further, in order to help control the three-dimensional shape of the source/drain features during the epitaxial growth process by helping the etching efficiency of the etching precursor during a cleaning process, a shaping precursor may be placed in the fourth precursor delivery system 310. In an embodiment the shaping precursor is a material that, when incorporated into the source/drain regions during the cleaning process, will help to amorphize and modify the crystalline structure of the source/drain regions that has already been grown prior to introduction of the shaping precursor. In a particular embodiment in which the grown material is silicon phosphorous, the shaping precursor is a material that comprises a material with a different crystalline lattice constant, such as germanium. In a particular embodiment the shaping precursor is GeH₄. Other suitable shaping precursor may be utilized.

Once the first precursor material, the second precursor material, the etching precursor, and the shaping precursor are ready in the first precursor delivery system 305, the second precursor delivery system 306, the third precursor delivery system 308, and the fourth precursor delivery system 310, respectively, the formation of the source/drain features may be initiated by the control unit sending an instruction to the precursor gas controller 313 to start a first step and connect the first precursor delivery system 305, the second precursor delivery system 306, and the third precursor delivery system 308 to the epitaxial growth chamber 303. Once connected, the first precursor delivery system 305, the second precursor delivery system 306 and the third precursor delivery system 308 can deliver the first precursor material (e.g., dichlorosilane), the second precursor material (e.g., PH₃), and the etching precursor (e.g., HCl) to the showerhead 317 through the precursor gas controller 313 and the manifold 316. The showerhead 317 can then disperse the first precursor material, the second precursor material, and the etching precursor into the epitaxial growth chamber 303, wherein the first precursor material and the second precursor material can react to the exposed surface of the fins 212 and begin to grow a bulk section of the source/drain features on the exposed sections of the fins 212.

In some embodiment, the source/drain features in an n-type transistor region and a p-type transistor region may be formed separately. For example, when the source/drain features for the n-type transistor region are epitaxially grown, the p-type transistor region may be covered under a resist layer which blocks epitaxial growth from occurring in the p-type transistor region. After the source/drain features in the n-type transistor region are formed, the source/drain features in the p-type transistor region are epitaxially grown, while the n-type transistor region is covered under a resist layer which blocks epitaxial growth from occurring in the n-type transistor region. Alternatively, the source/drain features in the p-type transistor region may be epitaxially grown prior to the source/drain features in the n-type transistor region.

In the n-type transistor region, the source/drain features may include Si, SiP, SiAs, SiC, SiCP, SiCAs, or other suitable semiconductor material. The source/drain features may be doped with dopants such as arsenic (As) or phosphorus (P). In one example, the source/drain features are doped with As or P with a molar concentration from about 5×10²⁰ cm⁻³ to about 4×10²¹ cm⁻³. When the source/drain features include carbon, a carbon atomic percentage may range from about 10% to about 20%. In the p-type transistor region, the source/drain features may include SiGe, SiSn, or other suitable semiconductor material. The source/drain features may be doped with dopants such as germanium (Ge) or boron (B). In one example, the source/drain features may be doped with boron (B) and the source/drain features include SiGeB, SiSnB, or other suitable semiconductor material with a boron molar concentration from about 4×10²⁰ cm⁻³ to about 2×10²¹ cm⁻³. When the source/drain features include germanium, a germanium atomic percentage may range from about 10% to about 60%.

FIGS. 18-20 illustrate the semiconductor device 200 at the conclusion of epitaxial growth process at block 122. FIG. 18 is a cross-sectional view of the semiconductor device 200 cut through one of the fins 212 along the B-B line in FIG. 15. FIG. 19 is a cross-sectional view of the semiconductor device 200 cut through one of the source/drain regions, which is previously covered by the cover structure 244, along the C-C line in FIG. 18. FIG. 20 is a cross-sectional view of the semiconductor device 200 cut through one of the source/drain regions, which is not previously covered by the cover structure 244, along the D-D line in FIG. 18.

The source/drain features epitaxially grown from the larger source/drain trenches 250a (FIG. 16) are denoted as source/drain features 260a, and the source/drain features epitaxially grown from the smaller source/drain trenches 250b and 250c (FIG. 16) are denoted as source/drain features 260b. In the depicted embodiment, since a sum of the volumes of the source/drain trenches 250b and 250c is still less than the volume of the source/drain trench 250a, the source/drain trenches 250b and 250c will be filled up faster than the source/drain trench 250a. In other words, the source/drain feature 260b has a faster growth rate in the Z direction than the source/drain feature 260a. Thus, the source/drain feature 260b is raised above the source/drain feature 260a, as shown in FIG. 18. The source/drain feature 260b has two lower portions in the source/drain trenches 250b and 250c, respectively, and a connecting portion adjoining the two lower portions. The connecting portion of the source/drain feature 260b is formed due to the two lower portions in the source/drain trenches 250b and 250c merged after they rise above the top surface of the fin 212.

Referring to FIGS. 19 and 20 collectively, for the same amount of the first precursor material and the second precursor material deposited to the source/drain regions in further reaction to form epitaxial features 260a and 260b, respectively, since there is less epitaxial material to fill in the smaller source/drain trenches 250b and 250c, more epitaxial material may be applied on the top portion of the source/drain features 260b to facilitate the vertical rising and lateral merging of the source/drain features 260b over the fins 212. As a comparison there is more epitaxial material to fill in the larger source/drain trenches 250a, and less epitaxial material may be applied to the top portion of the source/drain features 260a such that some of the source/drain features 260a may stay apart with gaps 264 therebetween. In the illustrated embodiment, the merged source/drain features 260b has a flat top surface and faceted sidewall surfaces with air gaps 262 between the merged source/drain features 260b and the isolation feature 216, and as a comparison the source/drain features 260a have sawtooth top surfaces interrupted by gaps 264 with air gaps 262 between the source/drain features 260a and the isolation feature 216. The poor lateral merging of the source/drain features 260a with gaps 264 therebetween may cause later formed source/drain contact to punch into the isolation feature 216 through the gaps 264 and may cause device performance degradation.

FIG. 21 illustrates another embodiment of the cover structure 244 at the conclusion of block 116. In this embodiment, the cover structure 244 includes two base portions 244a sandwiching the dummy gate stacks 230 along the Y direction and multiple source/drain cover portions 244b connecting the two base portions 244a and over each of the source/drain regions between two adjacent dummy gate stacks 230. Due to the source/drain cover portion 244b, each source/drain region at the conclusion of block 120 has two small source/drain trenches 250b and 250c spaced apart from each other, as shown in FIG. 22 which is a cross-sectional view of the semiconductor device 200 cut through one of the fins 212 along the B-B line in FIG. 21.

The resultant structure after the epitaxial growth process at the conclusion of block 122 is shown in FIGS. 23-25. FIG. 23 is a cross-sectional view of the semiconductor device 200 cut through one of the fins 212 along the B-B line in FIG. 15. FIG. 24 is a cross-sectional view of the semiconductor device 200 cut through one of the source/drain regions, which is previously covered by the cover structure 244, along either the C-C line in FIG. 23. FIG. 25 is a cross-sectional view of the semiconductor device 200 cut through one of the source/drain regions, which is previously covered by the cover structure 244, along the D-D line in FIG. 23. The source/drain features 260b is formed in each of the source/drain regions. Each of the source/drain features 260b includes two lower portions in the source/drain trenches 250b and 250c, respectively, and a connecting portion adjoining the two lower portions. The connecting portion of the source/drain feature 260b is formed due to the two lower portions in the source/drain trenches 250b and 250c merging after their rising above the top surface of the fin 212. For the same amount of the first precursor material and the second precursor material deposited to the source/drain regions in further reaction to form epitaxial features 260a and 260b, respectively, since there is less epitaxial material to fill in the smaller source/drain trenches 250b and 250c, more epitaxial material may be applied on the top portion of the source/drain features 260b to facilitate the vertical rising and lateral merging of the source/drain features 260b over the fins 212. In the illustrated embodiment, the merged source/drain features 260b have a flat top surface and faceted sidewall surfaces with air gaps 262 between the merged source/drain features 260b and the isolation feature 216.

Referring to FIG. 1 and FIGS. 26-27, method 100 includes a block 124 where further processes are performed. Such further processes may include, for example, deposition of a contact etch stop layer (CESL) 270 over the semiconductor device 200, deposition of an interlayer dielectric (ILD) layer 272 over the CESL 270, replacement of the dummy gate stacks 230 with metal gate stacks 274, formation of source/drain contacts 280 and gate contacts 284, and formation of an interconnect multilayer structure 286. FIG. 26 is a cross-sectional view of the semiconductor device 200 cut through one of the fins 212 along the B-B line in FIG. 21. FIG. 27 is a cross-sectional view of the semiconductor device 200 cut through one of the source/drain regions, which is previously covered by the cover structure 244, along the C-C line in FIG. 26.

The CESL 270 is formed prior to forming the ILD layer 272. In some examples, the CESL 270 includes silicon nitride, silicon oxynitride, and/or other materials known in the art. The CESL 270 may be formed by ALD, plasma-enhanced chemical vapor deposition (PECVD) process and/or other suitable deposition processes. The ILD layer 272 is then deposited over the CESL 270. In some embodiments, the ILD layer 272 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 272 may be deposited by a PECVD process or other suitable deposition technique. The CESL 270 is disposed directly on top surfaces of the source/drain features 260b (and 260a if present). After the deposition of the CESL 270 and the ILD layer 272, the semiconductor device 200 may be planarized by a planarization process to expose the dummy gate stacks 230. For example, the planarization process may include a chemical mechanical planarization (CMP) process.

Exposure of the dummy gate stacks 230 allows the removal of the dummy gate stacks 230. In some embodiments, the removal of the dummy gate stacks 230 results in gate trenches (not shown) over the channel regions. The removal of the dummy gate stacks 230 may include one or more etching processes that are selective to the material of the dummy gate stacks 230. For example, the removal of the dummy gate stacks 230 may be performed using as a selective wet etch, a selective dry etch, or a combination thereof that is selective to the dummy gate stacks 230.

Subsequently, the metal gate stacks 274 is formed within the gate trenches. The metal gate stacks 274 include a gate dielectric layer 276 and a gate electrode layer 278 over the gate dielectric layer 276. In some embodiments, while not explicitly shown in the figures, the gate dielectric layer 276 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 278 of the metal gate stacks 274 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 278 may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 278 may be formed by ALD, PVD, CVD, e-beam evaporation, or other suitable process.

In some embodiments, the source/drain contacts 280 and the gate contacts 284 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAIN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted. To reduce contact resistance, silicide features 282 may be formed between the source/drain contacts 280 and the source/drain features 260b (and 260a if present) In some embodiments, the silicide features 282 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. As shown in FIG. 27, the partially recessed source/drain regions facilitate the lateral merging of the source/drain features 260b over the fins 212. The merged source/drain features 260 prevent the source/drain contact 280 from punching through gaps otherwise existing between unmerged source/drain features.

The interconnect multilayer structure 286 includes vias 288 and metal lines 290 embedded in dielectric layers. The interconnect multilayer structure 286 connects gate, source, and drain features of various transistors, as well as other circuits in the semiconductor device 200, to form an integrated circuit in part or in whole. The semiconductor device 200 may further include passivation layers, adhesion layers, and/or other layers built on the frontside of the semiconductor device 200. These layers and the one or more interconnect layers are collectively denoted with the label 286.

FIG. 28 illustrates another embodiment of the cover structure 244 at the conclusion of block 116. In this embodiment, the cover structure 244 includes a single base portion 244a disposed on one side of the dummy gate stacks 230 and multiple protruding portions 244b. The first protruding portion 244b-1 does not extend into the source/drain region and does not cover any fin 212, the second protruding portion 244b-2 extends into the source/drain region and cover a few fins 212, and the third protruding portion 244b-3 extends further into the source/drain region and cover even more fins 212.

The resultant structure after the epitaxial growth process at the conclusion of block 122 is shown in FIG. 29. FIG. 29 is a cross-sectional view of the semiconductor device 200 cut through one of the fins 212 along the B-B line in FIG. 28. Source/drain feature 260a is formed in the large source/drain trench corresponding to the first protruding portion 244b-1, source/drain feature 260b-2 is formed in the small source/drain trenches corresponding to the second protruding portion 244b-2, and source/drain feature 260b-3 is formed in the small source/drain trenches corresponding to the third protruding portion 244b-3. Each of the source/drain features 260b-2 and 260b-3 has two lower portions in the source/drain trenches 250b and 250c, respectively, and a connecting portion adjoining the two lower portions. Even though none of the protruding portions 244b extends fully through the respective source/drain region in the Y direction, the protruding portions 244b-2 and 244b-3 still allow relatively less epitaxial material to fill in the respective source/drain trenches and thus more epitaxial material to deposit on top of the respective source/drain features. Therefore, the source/drain features 260b-2 and 260b-3 are both higher than the source/drain feature 260a, and the source/drain feature 260b-3 corresponding to the longer protruding portion 244b-3 is higher than the source/drain feature 260b-2 corresponding to the shorter protruding portion 244b-2.

FIG. 30 illustrates another embodiment of the cover structure 244 at the conclusion of block 116. In this embodiment, the cover structure 244 includes a single base portion 244a disposed on one side of the dummy gate stacks 230 and multiple protruding portions 244b. The first protruding portion 244b-1 extends into the middle source/drain region and cover a few (e.g., four) fins 212, and the second protruding portion 244b-2 extends into the right source/drain region and cover the same number of the fins 212. The source/drain region on the left has no corresponding protruding portion. The first protruding portion 244b-1 has a larger width measured in the X direction than the second protruding portion 244b-2.

The resultant structure after the epitaxial growth process at the conclusion of block 122 is shown in FIGS. 31-33. FIG. 31 is a cross-sectional view of the semiconductor device 200 cut through the left source/drain region along the D-D line in FIG. 30. FIG. 32 is a cross-sectional view of the semiconductor device 200 cut through the middle source/drain region along the C-C line in FIG. 30. FIG. 33 is a cross-sectional view of the semiconductor device 200 cut through the right source/drain region along the E-E line in FIG. 30. Source/drain feature 260a is formed in the large source/drain trench, source/drain feature 260b-2 is formed in the small source/drain trenches corresponding to the thinner protruding portion 244b-2, and source/drain feature 260b-1 is formed in the even smaller source/drain trenches corresponding to the wider protruding portion 244b-2.

For the same amount of the first precursor material and the second precursor material deposited to the source/drain regions in further reaction to form epitaxial features 260a, 260b-1, and 260b-2, respectively, since there is less epitaxial material to fill in the smaller source/drain trenches 250b and 250c, more epitaxial material may be applied on the top portion of the source/drain features 260b-1 and 260b-2 to facilitate the vertical rising and lateral merging of the source/drain features over the fins 212, while as a comparison there is more epitaxial material to fill in the larger source/drain trenches 250a, less epitaxial material may be applied to the top portion of the source/drain features 260a such that some of the source/drain features 260a may stay apart with gaps 264 therebetween. Comparing the source/drain features 260b-1 and 260b-2, the source/drain features 260b-1 and 260b-2 over the uncovered fins (e.g., five fins) also benefit from more epitaxial material deposited on the top portion of the source/drain features 260-1 and 260-2. Since the source/drain features 260b-1 have the smallest volume below the top surface of the fins 212, it has the largest volume above the top surface of the fins 212, and the top surface of the merged source/drain features 260b-1 is substantially flat. Similarly, the source/drain features 260b-2 have a relatively larger volume below the top surface of the fins 212, it has a relatively smaller volume above the top surface of the fins 212, and the top surface of the merged source/drain features 260b-2 has a sawtooth profile. The source/drain features 260a have the largest volume below the top surface of the fins 212, and some of the source/drain features 260a still stay apart.

FIG. 34 illustrates another embodiment of the cover structure 244 at the conclusion of block 116. In this embodiment, the cover structure 244 includes a single base portion 244a disposed on one side of the dummy gate stacks 230 and multiple protruding portions 244b. The first protruding portion 244b-1, the second protruding portion 244b-2, and the third protruding portion 244b-3 have the same width W1 but different distance to the respective nearest dummy gate stack 230. The second protruding portion 244b-2 is positioned at the center of two adjacent dummy gate stacks 230-2 and 230-3, the first protruding portion 244b-1 is positioned closer to the dummy gate stack 230-1 with a distance W2 and farther from the dummy gate stack 230-2 with a distance W3 (W2<W3), and the third protruding portion 244b-3 is positioned closer to the dummy gate stack 230-4 with a distance W2′ and father from the dummy gate stack 230-3 with a distance W3′ (W2′<W3′). The source/drain region between dummy gate structures 230-4 and 230-5 has no corresponding protruding portion.

The resultant structure after the epitaxial growth process at the conclusion of block 122 is shown in FIG. 35. FIG. 35 is a cross-sectional view of the semiconductor device 200 cut through one of the fins 212 along the B-B line in FIG. 34. Source/drain feature 260a is formed in the largest source/drain trench extending between the dummy gate stacks 230-4 and 230-5 as without having a source/drain cover structure portion. Source/drain features 260b-1, 260b-2, 260b-3 are formed in the smaller source/drain trenches corresponding to the first protruding portion 244b-1, the second protruding portion 244b-2, the third protruding portion 244b-3. Each of the source/drain features 260-1, 260b-2, 260b-3 has two lower portions in the source/drain trenches 250b and 250c (FIG. 16), respectively, and a connecting portion adjoining the two lower portions. Even though none of the protruding portions 244b extends fully through the source/drain region in the Y direction, the protruding portions 244b-1, 244b-2, 244b-3 still allow relatively less epitaxial material to fill in the respective source/drain trenches and thus more epitaxial material to deposit on top of the respective source/drain features. Therefore, the topmost portions of the source/drain features 260b-1, 260b-2, 260b-3 are all higher than the source/drain feature 260a.

Regarding the source/drain feature 260b-2, the two lower portions have the same width and same depth, and the top surface is substantially flat. Regarding the source/drain features 260b-1, the lower portion of the smaller width W2 is narrower and also shallower than the lower portion of the larger width W3, and the top surface is slanted with the lower edge abutting the dummy gate stack 230-1 and the higher edge abutting the dummy gate stack 230-2. Further, the lower edge of the source/drain feature 260b-1 is below the top surface of the source/drain feature 260b-2, and the higher edge of the source/drain feature 260b-1 is above the top surface of the source/drain feature 260b-2. Still further, the lower edge of the source/drain feature 260b-1 may be below the top surface of the source/drain feature 260a in some embodiments. In the depicted embodiment, the higher edge being located above the larger one of the two immediate adjacent trenches may be due to once the epitaxial feature is grown above the fin top 212, the vertical growth rate associated a larger opening will catch up and surpass the vertical growth rate associated with a smaller opening. Yet this phenomenon more occurs in the two immediate adjacent trenches between the same opposing gate spacer sidewalls. Regarding the source/drain features 260b-3, the lower portion of the smaller width W2′ is narrower and also shallower than the lower portion of the larger width W3′, and the top surface is slanted with the lower edge abutting the dummy gate stack 230-4 and the higher edge abutting the dummy gate stack 230-3. Further, the lower edge of the source/drain feature 260b-3 is below the top surface of the source/drain feature 260b-2, and the higher edge of the source/drain feature 260b-3 is above the top surface of the source/drain feature 260b-2. Still further, the lower edge of the source/drain feature 260b-3 may be below the top surface of the source/drain feature 260a in some embodiments. Similarly, in the depicted embodiment, the higher edge being located above the larger one of the two immediate adjacent trenches may be due to once the epitaxial feature is grown above the fin top 212, the vertical growth rate associated a larger opening will catch up and surpass the vertical growth rate associated with a smaller opening. Yet this phenomenon more occurs in the two immediate adjacent trenches between the same opposing gate spacer sidewalls.

FIG. 36 illustrates another embodiment of the cover structure 244 at the conclusion of block 116. In this embodiment, the cover structure 244 includes two base portions 244a-1 and 244a-2 sandwiching the dummy gate stacks 230 along the Y direction. The base portion 244a-1 includes a first protruding portion 244b-1 extending partially into the source/drain region between the dummy gate stacks 230-2 and 230-3, and a third protruding portion 244b-3 extending partially into the source/drain region between the dummy gate stacks 230-4 and 230-5. The base portion 244a-2 includes a second protruding portion 244b-2 extending partially into the source/drain region between the dummy gate stacks 230-3 and 230-4, and a fourth protruding portion 244b-4 extending partially into the source/drain region between the dummy gate stacks 230-4 and 230-5.

The resultant structure after the epitaxial growth process at the conclusion of block 122 is shown in FIGS. 37-40. FIG. 37 is a cross-sectional view of the semiconductor device 200 cut through the source/drain region between the dummy gate stacks 230-1 and 230-2 along the D-D line in FIG. 36. FIG. 38 is a cross-sectional view of the semiconductor device 200 cut through the source/drain region between the dummy gate stacks 230-2 and 230-3 along the C-C line in FIG. 36. FIG. 39 is a cross-sectional view of the semiconductor device 200 cut through the source/drain region between the dummy gate stacks 230-3 and 230-4 along the E-E line in FIG. 36. FIG. 40 is a cross-sectional view of the semiconductor device 200 cut through the source/drain region between the dummy gate stacks 230-4 and 230-5 along the F-F line in FIG. 36.

Source/drain feature 260a is formed in the larger source/drain trench extending between the dummy gate structures 230-1 and 230-2 as without having a source/drain cover structure portion. Source/drain features 260b-1, 260b-2, 260b-3 are formed in the smaller source/drain trenches corresponding to the first protruding portion 244b-1, the second protruding portion 244b-2, and collectively the third and fourth protruding portions 244b-3 and 244b-4, respectively.

For the same amount of the first precursor material and the second precursor material deposited to the source/drain regions in further reaction to form epitaxial features 260a, 260b-1, 260b-2, and 260b-3, respectively, since there is less epitaxial material to fill in the smaller source/drain trenches 250b and 250c (FIG. 16), more epitaxial material may be applied on the top portion of the source/drain features 260b-1, 260b-2, and 260b-3 to facilitate the vertical rising and lateral merging of the source/drain features over the fins 212, while as a comparison there is more epitaxial material to fill in the larger source/drain trenches 250a, less epitaxial material may be applied to the top portion of the source/drain features 260a such that some of the source/drain features 260a may stay apart with gaps 264 therebetween. Regarding the source/drain features 260b-1 and 260b-2, the source/drain features 260b-1 and 260b-2 over the six uncovered fins also benefit from more epitaxial material deposited on the top portion of the source/drain features 260-1 and 260-2 with all epitaxial features over the fins merged with a sawtooth top surface. The center portion of the source/drain feature 260b-3 is above the side portions of the source/drain feature 260b-3 and also above the other source/drain features 260b-1, 260b-2, and 260a. The source/drain features 260a are lower than source/drain features 260b-1, 260b-3, and 260b-3 due to its largest volume under the top surface of the fins 212.

FIGS. 41A-C illustrate various embodiments of the cover structure 244, and FIGS. 42A-C illustrate cross-sectional views of a transistor 400 corresponding to the cover structure 244 in FIGS. 41A-C along the B-B line, respectively. The transistor 400 may be an n-type transistor or a p-type transistor. The transistor 400 includes a channel region engaged by a metal gate stack 274. The channel region may be provided from a top portion of a fin in a FinFET transistor or a plurality of vertically stacked channel layers in a GAA transistor. In the context of a FinFET transistor, the metal gate stack 274 is deposited on a top and sidewalls of the fin. In the context of a GAA transistor, the metal gate stack 274 wraps around each of the suspended channel layers. The channel region of the transistor 400 is sandwiched between two source/drain features 260 along the X direction.

Referring to FIGS. 41A and 42A collectively, the cover structure 244 includes a base portion 244a but does not include a protruding portion or a protruding portion that extends into the source/drain regions, and consequently a single source/drain trench 250a (FIG. 16) is formed in each source/drain region. After the epitaxial growth process, source/drain features 260a are formed in the source/drain trenches 250a. The two source/drain features 260a of the transistor 400 have substantially same depth into the fin 212 and top surfaces that are level.

Referring to FIGS. 41B and 42B collectively, the cover structure 244 includes a base portion 244a with a protruding portion 244b partially extending into (or fully extending through) one of the source/drain regions along the Y direction, and consequently two small source/drain trenches 250b and 250c (FIG. 16) are formed at the portion of the source/drain region under the protruding portion 244b and a large source/drain trench 250a (FIG. 16) is formed in the other source/drain region. After the epitaxial growth process, a source/drain feature 260a is formed in the large source/drain trench 250a, and a source/drain feature 260b is formed in the two small source/drain trenches 250b and 250c. The source/drain feature 260a has a larger volume under the top surface of the fin 212 but a lower top surface. The source/drain feature 260b has a smaller volume under the top surface of the fin 212 but a higher top surface.

Referring to FIGS. 41C and 42C collectively, the cover structure 244 includes a base portion 244a with a first protruding portion 244b-1 partially extending into (or fully extending through) the source/drain region between the dummy gate stacks 230-1 and 230-2 along the Y direction and a second protruding portion 244b-2 partially extending into (or fully extending through) the source/drain region between the dummy gate stacks 230-2 and 230-3 along the Y direction. Consequently, two small source/drain trenches 250b and 250c (FIG. 16) are formed at the portion of the source/drain regions under the protruding portions 244b-1 and 244b-2. After the epitaxial growth process, source/drain features 260b are formed in the source/drain trenches 250b and 250c. Each of the source/drain features 260b has two lower portions in the source/drain trenches 250b and 250c, respectively, and a connecting portion adjoining the two lower portions. The two source/drain features 260b of the transistor 400 have substantially same depth into the fin 212 and top surfaces that are level. With the smaller volume under the top surface of the fin 212, more epitaxial growth occurs on the top surface of the source/drain features 260b, such that the epitaxial features 260b laterally merge in an elevated thickness over the fins 212.

The implementation of a source/drain cover structure prior to the recessing of the source/drain region allows more epitaxial material to redistribute to top portions of the source/drain features during the formation of the source/drain features, which facilitates lateral merging of the source/drain features over the fins. The source/drain cover structure may have different shapes, which allows fine tuning to the profiles of the source/drain features to meet different device performance needs.

In one exemplary aspect, the present disclosure is directed to a method of manufacturing a semiconductor device. The method includes forming a plurality of fins protruding from a substrate, each of the fins extending lengthwise in a first direction, forming first and second dummy gate stacks over the fins, each of the first and second dummy gate stacks extending lengthwise in a second direction different from the first direction, depositing a cover structure over the fins, a first portion of the cover structure extending lengthwise in the second direction between the first and second dummy gate stacks in a top view of the semiconductor device, etching the fins with the cover structure as an etch mask to form a first trench between the first dummy gate stack and the first portion of the cover structure and a second trench between the second dummy gate stack and the first portion of the cover structure in a cross-sectional view of the semiconductor device along the first direction, removing the cover structure, epitaxially growing a first epitaxial feature from the first trench and a second epitaxial feature from the second trench, the first and second epitaxial features merging after rising above a top surface of the fins to form a merged epitaxial feature, and replacing the first and second dummy gate stacks with first and second metal gate stacks, respectively. In some embodiments, the merged epitaxial feature extending continuously above the fins, such that each of the fins is directly under the merged epitaxial feature. In some embodiments, the cover structure including a second portion disposed aside the first and second dummy gate stacks in the top view, and the first portion is protruding from an edge of the second portion. In some embodiments, the cover structure including a third portion disposed aside the first and second dummy gate stacks in the top view, the second and third portions sandwich the first and second dummy gate stacks along the second direction. In some embodiments, the first portion connects the second and third portions. In some embodiments, the first portion overlaps with each of the fins in the top view. In some embodiments, the first portion is free of overlapping with a subset of the fins in the top view. In some embodiments, the first portion is spaced apart from the first dummy gate stack for a first distance along the first direction and spaced apart from the second dummy gate stack for a second distance along the second direction, and wherein the first distance equals the second distance. In some embodiments, the first portion is spaced apart from the first dummy gate stack for a first distance along the first direction and spaced apart from the second dummy gate stack for a second distance along the second direction, and wherein the first distance is smaller than the second distance. In some embodiments, the first epitaxial feature is shallower than the second epitaxial feature in the cross-sectional view.

In another exemplary aspect, the present disclosure is directed to a method of manufacturing a semiconductor device. The method includes patterning a substrate to form a fin, the fin having a first source/drain region, a second source/drain region, and a channel region between the first and second source/drain regions, forming a gate stack over the channel region of the fin, forming a cover structure having a first portion aside the gate stack and a second portion extending parallel to the gate stack and across the first source/drain region in a top view of the semiconductor device, recessing the first and second source/drain regions of the fin to form a first trench and a second trench in the first source/drain region and at least a third trench in the second source/drain region in a cross-sectional view of the semiconductor device cut along the fin, and epitaxially growing a first epitaxial feature from the first trench, a second epitaxial feature from the second trench, and a third epitaxial feature from the third trench. The first and second epitaxial features merge above a top surface of the fin. In some embodiments, the method also includes removing the cover structure, prior to the epitaxially growing of the first, second, and third epitaxial features. In some embodiments, the first portion extends parallel to the fin. In some embodiments, the cover structure is free of overlapping with the second source/drain region in the top view, and each of the first and second epitaxial features is shallower than the third epitaxial feature. In some embodiments, a top surface of the first and second epitaxial features is above a top surface of the third epitaxial feature. In some embodiments, the cover structure includes a third portion extending parallel to the gate stack and across the second source/drain region, the recessing forms a fourth trench in the second source/drain region, the epitaxially growing forms a fourth epitaxial feature from the fourth trench, and the third and fourth epitaxial features merge above the top surface of the fin.

In yet another exemplary aspect, the present disclosure is directed to a semiconductor device. The semiconductor device includes a substrate, a plurality of fins protruding from the substrate, each of the fins extending lengthwise in a first direction, a gate stack disposed over the fins, the gate stack extending lengthwise in a second direction perpendicular to the first direction, a first epitaxial feature disposed on a first side of the gate stack, and a second epitaxial feature disposed on a second side of the gate stack. The first epitaxial feature extends continuously such that each of the fins is directly under the first epitaxial feature. In a cross-sectional view of the semiconductor device cut along one of the fins, the first epitaxial feature includes a first lower portion extending below a top surface of the one of the fins, a second lower portion extending below the top surface of the one of the fins, and a connecting portion adjoining the first and second lower portions above the top surface of the one of the fins. In some embodiments, the second epitaxial feature is divided by at least one gap into a first segment apart from a second segment. In some embodiments, a top surface of the first epitaxial feature is substantially flat. In some embodiments, the first lower portion of the first epitaxial feature has a first bottom surface, the second lower portion of the second epitaxial feature has a second bottom surface, and the first bottom surface is above the second bottom surface.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a plurality of fins protruding from a substrate, each of the fins extending lengthwise in a first direction;
forming first and second dummy gate stacks over the fins, each of the first and second dummy gate stacks extending lengthwise in a second direction different from the first direction;
depositing a cover structure over the fins, a first portion of the cover structure extending lengthwise in the second direction between the first and second dummy gate stacks in a top view of the semiconductor device;
etching the fins with the cover structure as an etch mask to form a first trench between the first dummy gate stack and the first portion of the cover structure and a second trench between the second dummy gate stack and the first portion of the cover structure in a cross-sectional view of the semiconductor device along the first direction;
removing the cover structure;
epitaxially growing a first epitaxial feature from the first trench and a second epitaxial feature from the second trench, the first and second epitaxial features merging after rising above a top surface of the fins to form a merged epitaxial feature; and
replacing the first and second dummy gate stacks with first and second metal gate stacks, respectively.

2. The method of claim 1, wherein the merged epitaxial feature extending continuously above the fins, such that each of the fins is directly under the merged epitaxial feature.

3. The method of claim 1, wherein the cover structure including a second portion disposed aside the first and second dummy gate stacks in the top view, and the first portion is protruding from an edge of the second portion.

4. The method of claim 3, wherein the cover structure including a third portion disposed aside the first and second dummy gate stacks in the top view, the second and third portions sandwich the first and second dummy gate stacks along the second direction.

5. The method of claim 4, wherein the first portion connects the second and third portions.

6. The method of claim 1, wherein the first portion overlaps with each of the fins in the top view.

7. The method of claim 1, wherein the first portion is free of overlapping with a subset of the fins in the top view.

8. The method of claim 1, wherein the first portion is spaced apart from the first dummy gate stack for a first distance along the first direction and spaced apart from the second dummy gate stack for a second distance along the second direction, and wherein the first distance equals the second distance.

9. The method of claim 1, wherein the first portion is spaced apart from the first dummy gate stack for a first distance along the first direction and spaced apart from the second dummy gate stack for a second distance along the second direction, and wherein the first distance is smaller than the second distance.

10. The method of claim 8, wherein the first epitaxial feature is shallower than the second epitaxial feature in the cross-sectional view.

11. A method of manufacturing a semiconductor device, comprising:
patterning a substrate to form a fin, the fin having a first source/drain region, a second source/drain region, and a channel region between the first and second source/drain regions;
forming a gate stack over the channel region of the fin;
forming a cover structure having a first portion aside the gate stack and a second portion extending parallel to the gate stack and across the first source/drain region in a top view of the semiconductor device;
recessing the first and second source/drain regions of the fin to form a first trench and a second trench in the first source/drain region and at least a third trench in the second source/drain region in a cross-sectional view of the semiconductor device cut along the fin; and
epitaxially growing a first epitaxial feature from the first trench, a second epitaxial feature from the second trench, and a third epitaxial feature from the third trench, wherein the first and second epitaxial features merge above a top surface of the fin.

12. The method of claim 11, further comprising:
removing the cover structure, prior to the epitaxially growing of the first, second, and third epitaxial features.

13. The method of claim 11, wherein the first portion extends parallel to the fin.

14. The method of claim 11, wherein the cover structure is free of overlapping with the second source/drain region in the top view, and each of the first and second epitaxial features is shallower than the third epitaxial feature.

15. The method of claim 14, wherein a top surface of the first and second epitaxial features is above a top surface of the third epitaxial feature.

16. The method of claim 11, wherein the cover structure includes a third portion extending parallel to the gate stack and across the second source/drain region, the recessing forms a fourth trench in the second source/drain region, the epitaxially growing forms a fourth epitaxial feature from the fourth trench, and the third and fourth epitaxial features merge above the top surface of the fin.

17. A semiconductor device, comprising:
a substrate;
a plurality of fins protruding from the substrate, each of the fins extending lengthwise in a first direction;
a gate stack disposed over the fins, the gate stack extending lengthwise in a second direction perpendicular to the first direction;
a first epitaxial feature disposed on a first side of the gate stack; and
a second epitaxial feature disposed on a second side of the gate stack,
wherein:
the first epitaxial feature extends continuously such that each of the fins is directly under the first epitaxial feature, and
in a cross-sectional view of the semiconductor device cut along one of the fins, the first epitaxial feature includes a first lower portion extending below a top surface of the one of the fins, a second lower portion extending below the top surface of the one of the fins, and a connecting portion adjoining the first and second lower portions above the top surface of the one of the fins.

18. The semiconductor device of claim 17, wherein the second epitaxial feature is divided by at least one gap into a first segment apart from a second segment.

19. The semiconductor device of claim 17, wherein a top surface of the first epitaxial feature is substantially flat.

20. The semiconductor device of claim 17, wherein the first lower portion of the first epitaxial feature has a first bottom surface, the second lower portion of the second epitaxial feature has a second bottom surface, and the first bottom surface is above the second bottom surface.
